(19) United States
(12) Patent Application Publication
(10) Pub. No.: US 2024/0055457 A1
(43) Pub. Date: Feb. 15, 2024

(54) PHOTODETECTION DEVICE, ELECTRONIC DEVICE, AND DISTANCE MEASURING SYSTEM

(71) Applicant: SONY SEMICONDUCTOR SOLUTIONS CORPORATION, Kanagawa (JP)

(72) Inventors: Mutsumi OKAZAKI, Kanagawa (JP); Yusuke OTAKE, Kanagawa (JP)

(73) Assignee: SONY SEMICONDUCTOR SOLUTIONS CORPORATION, Kanagawa (JP)

(21) Appl. No.: 18/260,674

(22) PCT Filed: Dec. 22, 2021
(86) PCT No.: PCT/JP2021/047601

§ 371 Date: Jul. 7, 2023

(30) Foreign Application Priority Data
Jan. 20, 2021 (JP) 2021-007033

(51) Int. Cl. H01L 27/146; G01S 7/481; G01S 17/08

(52) U.S. Cl. CPC H01L 27/14629; H01L 27/14649; G01S 7/4816; G01S 17/08

(57) ABSTRACT

A photodetection device is provided which includes a pixel array unit including a plurality of pixels arranged in a matrix on a semiconductor substrate to detect light, in which each of the pixels includes a pixel separation wall that surrounds the pixels and separates the pixels from one another, a photoelectric conversion unit inside the semiconductor substrate to generate an electric charge by light, a multiplication region inside the semiconductor substrate to multiply the electric charge from the photoelectric conversion unit, and first and second reflective portions that reflect light traveling toward outside the semiconductor substrate into the semiconductor substrate, the first reflective portion is provided, on a first surface that receives light of the semiconductor substrate, to protrude from the pixel separation wall toward a pixel center, and the second reflective portion is provided on a second surface of the semiconductor substrate facing the first surface.

### FIELD

The present disclosure relates to a photodetection device, an electronic device, and a distance measuring system.

### BACKGROUND

In recent years, a distance measuring system that measures a distance by a time of flight (ToF) method has attracted attention. Examples of a light-receiving element included in the distance measuring system have a light-receiving element using a single photon avalanche diode (SPAD). In the SPAD, one light (photon) is incident, and electrons (electric charges) generated by photoelectric conversion are multiplied in a PN junction region (avalanche multiplication), whereby the light can be detected with high accuracy. In the distance measuring system, the distance can be measured with high accuracy by detecting the timing at which a current by the multiplied electrons flows.

### CITATION LIST

### Patent Literature

Patent Literature 1: WO 2018/074530 A

### SUMMARY

### Technical Problem

The SPADs are required to further improve the efficiency of light detection called photon detection efficiency (PDE) in order to accurately perform distance measurement. However, the SPADs that have been studied conventionally have limitations in improving the photon detection efficiency (PDE).

In view of this, the present disclosure proposes a photodetection device, an electronic device, and a distance measuring system capable of further improving the photon detection efficiency.

### Solution to Problem

According to the present disclosure, there is provided a photodetection device including: a pixel array unit including a plurality of pixels that is arranged in a matrix on a semiconductor substrate to detect light. In the photodetection device, each of the pixels includes a pixel separation wall that surrounds the pixels and separates the pixels from one another, a photoelectric conversion unit that is provided inside the semiconductor substrate to generate an electric charge by light, a multiplication region that is provided inside the semiconductor substrate to multiply the electric charge from the photoelectric conversion unit, and first and second reflective portions that reflect light traveling toward outside the semiconductor substrate into the semiconductor substrate, the first reflective portion is provided, on a first surface that receives light of the semiconductor substrate, to protrude from the pixel separation wall toward a pixel center, and the second reflective portion is provided on a second surface of the semiconductor substrate facing the first surface.

Furthermore, according to the present disclosure, there is provided an electronic device mounting a photodetection device. The photodetection device includes a pixel array unit including a plurality of pixels that is arranged in a matrix on a semiconductor substrate to detect light. In the photodetection device, each of the pixels includes a pixel separation wall that surrounds the pixels and separates the pixels from one another, a photoelectric conversion unit that is provided inside the semiconductor substrate to generate an electric charge by light, a multiplication region that is provided inside the semiconductor substrate to multiply the electric charge from the photoelectric conversion unit, and first and second reflective portions that reflect light traveling toward outside the semiconductor substrate into the semiconductor substrate, the first reflective portion is provided, on a first surface that receives light of the semiconductor substrate, to protrude from the pixel separation wall toward a pixel center, and the second reflective portion is provided on a second surface of the semiconductor substrate facing the first surface.

Furthermore, according to the present disclosure, there is provided a distance measuring system including an illumination device that emits irradiation light; and a photodetection device that receives reflected light obtained by reflecting the irradiation light being reflected by a subject. In the distance measuring system, the photodetection device includes a pixel array unit including a plurality of pixels that is arranged in a matrix on a semiconductor substrate to detect light, each of the pixels includes a pixel separation wall that surrounds the pixels and separates the pixels from one another, a photoelectric conversion unit that is provided inside the semiconductor substrate to generate an electric charge by light, a multiplication region that is provided inside the semiconductor substrate to multiply the electric charge from the photoelectric conversion unit, and first and second reflective portions that reflect light traveling toward outside the semiconductor substrate into the semiconductor substrate, the first reflective portion is provided, on a first surface that receives light of the semiconductor substrate, to protrude from the pixel separation wall toward a pixel center, and the second reflective portion is provided on a second surface of the semiconductor substrate facing the first surface.

### BRIEF DESCRIPTION OF DRAWINGS

FIG. 1 is an explanatory diagram for explaining an example of a circuit configuration of a pixel 10.

FIG. 2 is a graph illustrating a change in a cathode voltage VS of a photodiode 20 according to incidence of light and a detection signal PFₒᵤₜ.

FIG. 3 is a block diagram illustrating a configuration example of a photodetection device 501.

FIG. 4 is a block diagram illustrating a configuration example of a distance measuring system 611 incorporating the photodetection device 501 therein.

FIG. 5 is a schematic plan view illustrating an example of a detailed configuration of a pixel 10a according to a comparative example.

FIG. 6 is a schematic cross-sectional view illustrating an example of a detailed configuration of the pixel 10a according to a comparative example.

FIG. 7 is a schematic plan view illustrating an example of a detailed configuration of a pixel 10 according to a first embodiment of the present disclosure.

FIG. 8 is a schematic cross-sectional view illustrating an example of a detailed configuration of the pixel 10 according to the first embodiment of the present disclosure.

FIG. 9 is a schematic plan view illustrating an example of a detailed configuration of a pixel 10 according to a second embodiment of the present disclosure.

FIG. 10 is a schematic cross-sectional view (No. 1) illustrating an example of a detailed configuration of the pixel 10 according to the second embodiment of the present disclosure.

FIG. 11 is a schematic cross-sectional view (No. 2) illustrating an example of a detailed configuration of the pixel 10 according to the second embodiment of the present disclosure.

FIG. 12 is a schematic plan view illustrating an example of a detailed configuration of a pixel 10 according to a third embodiment of the present disclosure.

FIG. 13 is an explanatory diagram for explaining a detailed configuration of a pixel 10 according to a fourth embodiment of the present disclosure.

FIG. 14 is an explanatory diagram for explaining a detailed configuration of a pixel 10 according to a fifth embodiment of the present disclosure.

FIG. 15A is a schematic plan view illustrating an example of a detailed configuration of a pixel array unit 512 according to a sixth embodiment of the present disclosure.

FIG. 15B is a schematic plan view illustrating an example of a detailed configuration of a pixel 10 according to the sixth embodiment of the present disclosure.

FIG. 15C is a schematic cross-sectional view (No. 1) illustrating an example of a detailed configuration of the pixel 10 according to the sixth embodiment of the present disclosure.

FIG. 15D is a schematic cross-sectional view (No. 2) illustrating an example of a detailed configuration of the pixel 10 according to the sixth embodiment of the present disclosure.

FIG. 16A is a schematic diagram (No. 1) for explaining a method for manufacturing a pixel 10 according to a seventh embodiment of the present disclosure.

FIG. 16B is a schematic diagram (No. 2) for explaining a method for manufacturing the pixel 10 according to the seventh embodiment of the present disclosure.

FIG. 16C is a schematic diagram (No. 3) for explaining a method for manufacturing the pixel 10 according to the seventh embodiment of the present disclosure.

FIG. 16D is a schematic diagram (No. 4) for explaining a method for manufacturing the pixel 10 according to the seventh embodiment of the present disclosure.

FIG. 16E is a schematic diagram (No. 5) for explaining a method for manufacturing the pixel 10 according to the seventh embodiment of the present disclosure.

FIG. 16F is a schematic diagram (No. 6) for explaining a method for manufacturing the pixel 10 according to the seventh embodiment of the present disclosure.

FIG. 17 is a block diagram illustrating a configuration example of a smartphone 900 as an electronic device to which a distance measuring system 611 according to an embodiment of the present disclosure is applied.

### DESCRIPTION OF EMBODIMENTS

Hereinafter, embodiments of the present disclosure are described in detail with reference to the drawings. In the following embodiments, the same parts are denoted with the same reference numerals and repeated explanation of these parts is omitted.

The drawings referred to in the following description are drawings for explaining the embodiments of the present disclosure and facilitating understanding thereof, and shapes, dimensions, ratios, and the like illustrated in the drawings may be different from actual ones for the sake of clarity. Further, a photodetection device, constituent elements included in the photodetection device, and the like illustrated in the drawings can be appropriately modified in design in consideration of the following description and known techniques. Further, in the following description, the vertical direction of a laminated structure of the photodetection device corresponds to a relative direction for a case where the photodetection device is arranged such that light entering the photodetection device is directed from the bottom to the top unless otherwise specified.

The description of specific shapes in the following description does not mean only geometrically defined shapes. Specifically, the description of a specific shape in the following description includes a case where there is an allowable difference (error/distortion) in a pixel, a photodetection device, a manufacturing process thereof, and use/operation thereof, and includes a shape similar to the shape. In the following description, the expression “substantially rectangular shape” is not limited to a quadrangle, and includes, for example, a shape similar to a quadrangle in which any of four corners is chamfered.

In the following description of circuits (electrical connections), unless otherwise specified, “electrically connected” means that a plurality of elements is connected such that electricity (signal) flows. In addition, “electrically connected” in the following description includes not only a case of directly and electrically connecting a plurality of elements but also a case of indirectly and electrically connecting a plurality of elements via another element.

In the present specification, a “gate” represents a gate electrode of a field effect transistor. A “drain” represents a drain region of the field effect transistor, and a “source” represents a source region of the field effect transistor. A “first conductivity type” represents either a “p-type” or an “n-type”, and a “second conductivity type” represents the other of the “p-type” or the “n-type” different from the “first conductivity type”.

In the following description, “provided in common” means that another element is provided so as to be shared with a plurality of certain elements unless otherwise specified, in other words, the other element is shared with each of a predetermined number of certain elements.

Hereinafter, modes for implementing the present disclosure will be described in detail with reference to the drawings. The description will be given in the following order.
1. Background to creation of embodiments of present disclosure by inventors
1.1 Circuit configuration of pixel 10
1.2 Configuration example of photodetection device 501
1.3 Configuration example of distance measuring system 611
1.4 Detailed configuration of pixel 10a according to comparative example
1.5 Background
2. First Embodiment
2.1 Planar configuration
2.2 Cross-sectional configuration
3. Second Embodiment
3.1 Planar configuration
3.2 Cross-sectional configuration
4. Third Embodiment
5. Fourth Embodiment
6. Fifth Embodiment
7. Sixth Embodiment
8. Seventh Embodiment
9. Summary
10. Application example
11. Supplement

### 1. BACKGROUND TO CREATION OF EMBODIMENTS OF PRESENT DISCLOSURE BY INVENTORS

<1.1 Circuit Configuration of Pixel 10>

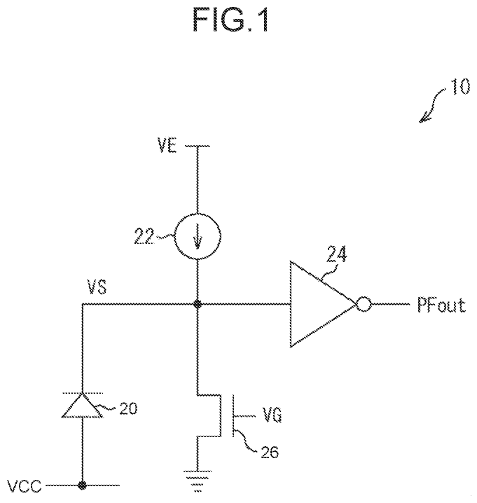

First, before describing details of embodiments of the present disclosure, an example of a circuit configuration of a pixel 10 to which the embodiments of the present disclosure are applicable will be described with reference to FIG. 1. FIG. 1 is an explanatory diagram for explaining an example of the circuit configuration of the pixel 10. Specifically, FIG. 1 illustrates the circuit configuration of the pixel 10 including a photodiode (light-receiving element) 20 having a single photon avalanche diode (SPAD) structure applicable to a distance measuring sensor that measures a distance by a direct time-of-flight (ToF) method.

As illustrated in FIG. 1, the pixel 10 includes the photodiode 20, a constant current source 22, an inverter 24, and a transistor 26.

As described above, the photodiode 20 has the SPAD structure, and can be operated at a bias voltage larger than a breakdown voltage VBD (Geiger mode). The photodiode 20 is an element that can detect one light (photon) for each pixel 10 by multiplying electrons (electric charges) generated by photoelectric conversion in a PN junction region of a high electric field provided for each pixel 10. Specifically, the photodiode 20 is a photodiode (single photon avalanche photodiode) that causes an avalanche multiplication of electrons (electric charges) generated by incident light and outputs a signal voltage VS obtained as a result of the multiplication to the inverter 24. The photodiode 20 includes a cathode electrically connected to the constant current source 22, an input terminal of the inverter 24, and a drain of the transistor 26. The photodiode 20 also has an anode electrically connected to a power supply. For example, in order to efficiently detect light (photons), a voltage (hereinafter, referred to as excess bias) larger than the breakdown voltage VBD of the photodiode 20 is applied to the photodiode 20. Further, a power supply voltage VCC supplied to the anode of the photodiode 20 is, for example, a negative bias (negative potential) having the same voltage as the breakdown voltage VBD of the photodiode 20.

The constant current source 22 includes, for example, a p-type metal oxide semiconductor (MOS) transistor operating in a saturation region, and performs passive quenching by acting as a quenching resistor. The constant current source 22 is supplied with a power supply voltage VE. The constant current source 22 may use a pull-up resistor or the like instead of the p-type MOS transistor.

The transistor 26 has the drain connected to the cathode of the photodiode 20, the input terminal of the inverter 24, and the constant current source 22, and has a source connected to the ground (GND). The transistor 26 has a gate to which a control signal is supplied from a pixel drive unit (not illustrated) that drives the pixel 10. Specifically, in a case where the pixel 10 is set as an effective pixel, a low (Lo) control signal is supplied from the pixel drive unit to the gate of the transistor 26. On the other hand, in a case where the pixel 10 is not set as an effective pixel, a high (Hi) control signal is supplied from the pixel drive unit to the gate of the transistor 26. Note that, here, the effective pixel is a pixel in a state in which light can be detected, and on the other hand, a pixel that is not set as the effective pixel means a pixel that does not detect light.

Then, the inverter 24 outputs a Hi signal PFₒᵤₜ in a case where the voltage VS from the cathode of the photodiode 20 as an input signal is Lo, and outputs a Lo signal PFₒᵤₜ in a case where the voltage VS from the cathode is Hi.

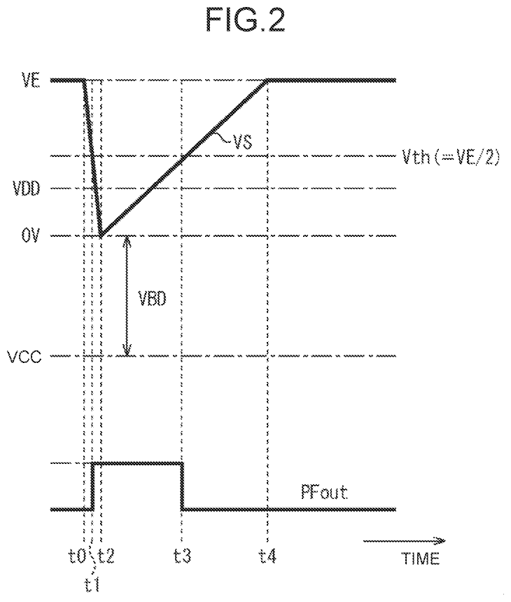

Next, an operation in a case where the pixel 10 is set as an effective pixel will be described with reference to FIG. 2. FIG. 2 is a graph illustrating a change in the cathode voltage VS of the photodiode 20 according to incidence of light and a detection signal PFₒᵤₜ.

First, in a case where the pixel 10 is an effective pixel, the transistor 26 is set to OFF by a Lo control signal. Then, at a time before time to, the power supply voltage VE is supplied to the cathode of the photodiode 20, and the power supply VCC is supplied to the anode. Thus, a reverse voltage larger than the breakdown voltage VBD is applied to the photodiode 20, so that the photodiode 20 is set to Geiger mode. In this state, the cathode voltage VS of the photodiode 20 is the same as the power supply voltage VE.

In response to light entering the photodiode 20 set in Geiger mode, avalanche multiplication occurs, and a current flows through the photodiode 20. Specifically, in a case where avalanche multiplication occurs at a time t0 and a current flows through the photodiode 20, the current also flows through the p-type MOS transistor as the constant current source 22, and a voltage drop occurs due to a resistance component of the MOS transistor.

Further, in a case where the cathode voltage VS of the photodiode 20 becomes lower than 0 V, a reverse voltage smaller than the breakdown voltage VBD is applied to the photodiode 20, so that the avalanche multiplication stops. Here, an operation in which the current generated by the avalanche multiplication flows through the constant current source 22 to generate a voltage drop, and the cathode voltage VS becomes lower than 0 V in association with the voltage drop to stop the avalanche multiplication is referred to as a quenching operation.

Then, in a case where the avalanche multiplication stops at a time t2, the current flowing through the constant current source 22 gradually decreases, and thus, at a time t4, the cathode voltage VS is recovered again to the original power supply voltage VE, and the photodiode 20 is ready to newly detect light (recharge operation).

For example, the inverter 24 outputs a low (Lo) PFₒᵤₜ signal in a case where the cathode voltage VS as an input voltage is equal to or higher than a predetermined threshold voltage Vth (=VE/2), and outputs a Hi PFₒᵤₜ signal in a case where the cathode voltage VS is lower than the predetermined threshold voltage Vth. In the example illustrated in FIG. 2, a high (Hi) PFₒᵤₜ signal is output in a period from a time t1 to a time t3.

In a case where the pixel 10 is not set as an effective pixel, a Hi control signal is supplied from the pixel drive unit (not illustrated) to the gate of the transistor 26, and the transistor 26 is turned on. As a result, the cathode voltage VS of the photodiode 20 becomes 0 V (GND) and the anode-cathode voltage of the photodiode 20 becomes equal to or lower than the breakdown voltage VBD; therefore, no current is generated even if light enters the photodiode 20.

<1.2 Configuration Example of Photodetection Device 501>

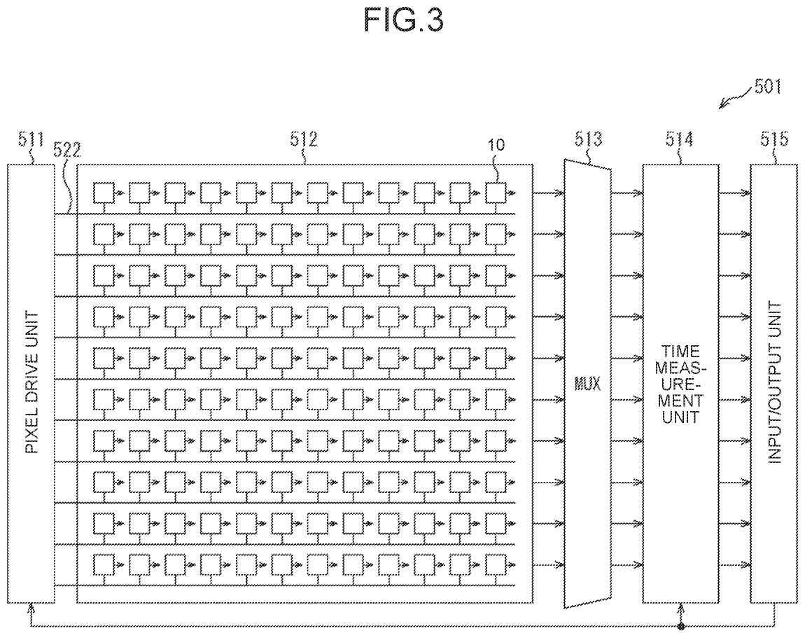

The pixel 10 described above can be used as, for example, a pixel of the photodetection device 501 illustrated in FIG. 3. FIG. 3 is a block diagram illustrating a configuration example of the photodetection device 501.

As illustrated in FIG. 3, for example, the photodetection device 501 includes a pixel drive unit 511, a pixel array unit 512, a multiplexer (MUX) 513, a time measurement unit 514, and an input/output unit 515. Hereinafter, details of each block included in the photodetection device 501 will be sequentially described.

(Pixel drive unit 511)

In the pixel array unit 512 described later, the pixels 10 are arranged in a matrix, and a pixel drive line 522 is wired along the horizontal direction for each row of the pixels 10. The pixel drive unit 511 drives each pixel 10 by supplying a predetermined drive signal to each pixel 10 via the pixel drive line 522. Specifically, the pixel drive unit 511 can perform control to set some of the plurality of pixels 10 two-dimensionally arranged in a matrix as effective pixels at a timing according to a light emission timing signal supplied from the outside via the input/output unit 515 described later.

(Pixel Array Unit 512)

The pixel array unit 512 has a configuration in which the pixels 10 that detect light and output a detection signal PFₒᵤₜ indicating the detection result as a pixel signal are two-dimensionally arranged in a matrix (matrix) in the row direction and the column direction. The number of rows and the number of columns of the pixels 10 of the pixel array unit 512 are not limited to the numbers illustrated in FIG. 3. As described above, the pixel drive line 522 is wired along the horizontal direction for each pixel row with respect to the matrix-like pixel array in the pixel array unit 512. The pixel drive line 522 is illustrated as a single wire, but may be configured by a plurality of wires. One end of the pixel drive line 522 is connected to an output end corresponding to each pixel row of the pixel drive unit 511.

(MUX 513)

The MUX 513 can select an output from an effective pixel according to switching between effective pixels and non-effective pixels in the pixel array unit 512 and output a pixel signal input from the selected effective pixel to the time measurement unit 514 described later.

(Time Measurement Unit 514)

The time measurement unit 514 generates, based on the pixel signal of the effective pixel supplied from the MUX 513 and the light emission timing signal indicating the light emission timing of a light emission source (not illustrated), a count value corresponding to a time period from when the light emission source emits light to when the effective pixel detects the light. Note that the light emission timing signal is supplied from the outside via the input/output unit 515 described later.

(Input/Output Unit 515)

The input/output unit 515 outputs the count value of the effective pixels supplied from the time measurement unit 514 to the outside as the pixel signal. The input/output unit 515 also supplies, to the pixel drive unit 511 and the time measurement unit 514, the light emission timing signal supplied from the outside.

<1.3 Configuration Example of Distance Measuring System 611>

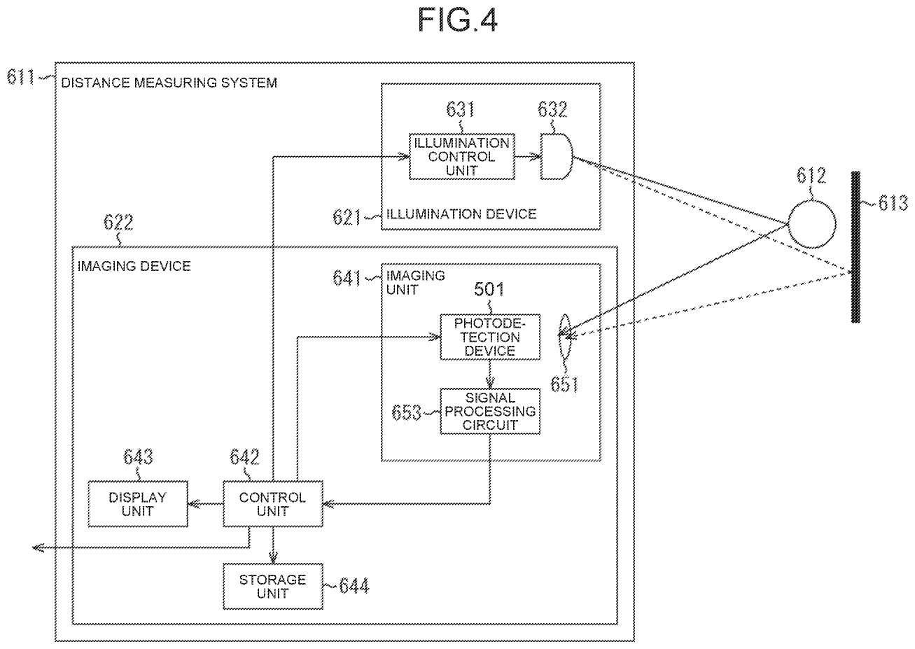

The photodetection device 501 described above can be applied to, for example, the distance measuring system 611 illustrated in FIG. 4. FIG. 4 is a block diagram illustrating a configuration example of the distance measuring system 611 incorporating the photodetection device 501 therein. The distance measuring system 611 is, for example, a system that captures a distance image using the ToF method. The distance image herein is an image including a distance pixel signal based on a distance detected in a depth direction from the distance measuring system 611 to subjects 612 and 613 for each pixel 10.

As illustrated in FIG. 4, the distance measuring system 611 includes an illumination device 621 and an imaging device 622. Hereinafter, details of each block included in the distance measuring system 611 will be sequentially described.

(Illumination Device 621)

As illustrated in FIG. 4, the illumination device 621 includes an illumination control unit 631 and a light source 632. The illumination control unit 631 controls a pattern, where the light source 632 emits light, under control of a control unit 642 of the imaging device 622. Specifically, the illumination control unit 631 controls the pattern, where the light source 632 emits light, according to an irradiation code included in an irradiation signal supplied from the control unit 642. For example, the irradiation code is a binary value of 1 (High) or 0 (Low), and the illumination control unit 631 causes the light source 632 to emit light when the value of the irradiation code is 1, and the illumination control unit 631 causes the light source 632 not to emit light when the value of the irradiation code is 0.

The light source 632 emits light of a predetermined wavelength region under the control of the illumination control unit 631. The light source 632 may include, for example, an infrared laser diode. Note that the type of the light source 632 and the wavelength region of the irradiation light can be arbitrarily set according to the usage and the like of the distance measuring system 611.

(Imaging device 622)

The imaging device 622 is a device that receives reflected light obtained in response to light (irradiation light) emitted from the illumination device 621 reflected by the subject 612, the subject 613, and the like. As illustrated in FIG. 4, the imaging device 622 includes an imaging unit 641, the control unit 642, a display unit 643, and a storage unit 644.

Specifically, as illustrated in FIG. 4, the imaging unit 641 includes a lens 651, a signal processing circuit 653, and the photodetection device 501. The lens 651 can form an image of the incident light on a light-receiving surface of the photodetection device 501. Here, the configuration of the lens 651 is arbitrarily determined, and for example, a plurality of lens groups can constitute the lens 651.

The photodetection device 501 can be the photodetection device 501 described above. Under the control of the control unit 642, the photodetection device 501 receives reflected light from the subject 612, the subject 613, and the like, and supplies a pixel signal obtained accordingly to the signal processing circuit 653. Specifically, the pixel signal indicates a digital count value obtained by counting a time from when the illumination device 621 emits the irradiation light to when the photodetection device 501 receives the irradiation light. The light emission timing signal indicating the timing at which the light source 632 emits light is supplied from the control unit 642 to the photodetection device 501.

The signal processing circuit 653 performs processing of the pixel signal supplied from the photodetection device 501 under the control of the control unit 642. For example, the signal processing circuit 653 detects a distance to the subjects 612 and 613 for each pixel 10 based on the pixel signal supplied from the photodetection device 501, and generates a distance image indicating the distance to the subjects 612 and 613 for each pixel 10. Specifically, the signal processing circuit 653 acquires, for each pixel 10, a time (count value) from when the light source 632 emits light to when each pixel 10 of the photodetection device 501 receives the light a plurality of times (for example, several thousands to several tens of thousands of times). The signal processing circuit 653 creates a histogram corresponding to the acquired time. The signal processing circuit 653 then detects the peak of the histogram to determine the time until the light emitted from the light source 632 is reflected by the subject 612 or the subject 613 and returns. Further, the signal processing circuit 653 performs calculation to obtain the distances to the subjects 612 and 613 based on the determined time and light speed. The signal processing circuit 653 then supplies the generated distance image to the control unit 642.

The control unit 642 includes, for example, a control circuit, a processor, and the like such as a field programmable gate array (FPGA) or a digital signal processor (DSP). The control unit 642 controls the illumination control unit 631 and the photodetection device 501. Specifically, the control unit 642 supplies an irradiation signal to the illumination control unit 631 and supplies a light emission timing signal to the photodetection device 501. The light source 632 emits irradiation light according to the irradiation signal. The light emission timing signal may be an irradiation signal supplied to the illumination control unit 631. The control unit 642 supplies the distance image acquired from the imaging unit 641 to the display unit 643 and causes the display unit 643 to display the distance image. Further, the control unit 642 stores the distance image acquired from the imaging unit 641 into the storage unit 644. The control unit 642 also outputs the distance image acquired from the imaging unit 641 to the outside.

The display unit 643 includes, for example, a panel type display device such as a liquid crystal display device and an organic electro luminescence (EL) display device.

The storage unit 644 can include an arbitrary storage device and a storage medium, and stores a distance image and the like.

<1.4 Detailed Configuration of Pixel 10a According to Comparative Example>

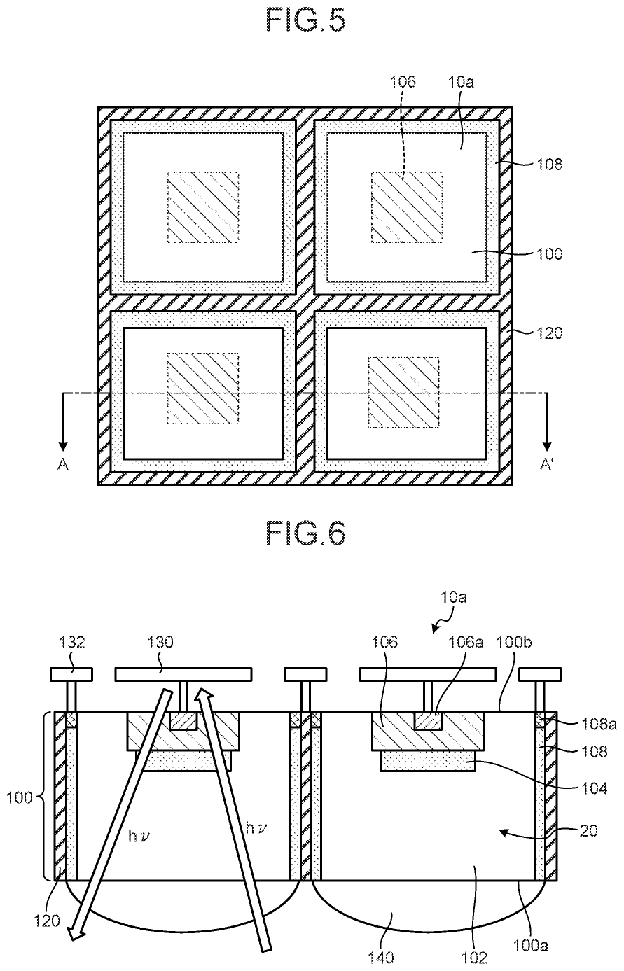

Next, an example of a detailed configuration of the pixel 10a according to a comparative example compared with the embodiments of the present disclosure will be described with reference to FIGS. 5 and 6. FIG. 5 is a schematic plan view illustrating an example of a detailed configuration of the pixel 10a according to the comparative example, and specifically illustrates a plane viewed from a back surface 100a (see FIG. 6) side of a semiconductor substrate 100 in which four pixels 10a are arranged in a matrix. FIG. 6 is a schematic cross-sectional view illustrating an example of a detailed configuration of the pixel 10a according to the comparative example, and specifically illustrates a cross section taken along a line A-A′ illustrated in FIG. 5. In FIGS. 5 and 6, the positional relationship of the constituent elements is schematically illustrated for easy understanding, and the configuration of FIGS. 5 and 6 may be different from the actual configuration. Here, the comparative example means the pixel 10a that has been repeatedly studied by the inventors before the embodiments of the present disclosure are made.

In the following description, it is assumed that the pixel is a back-illuminated pixel 10a on which light is incident from the lower surface (back surface 100a) side in FIG. 6. However, the pixel 10a is not limited to the back-illuminated pixel, and may be a front-illuminated pixel 10a on which light is incident via a wiring layer (not illustrated) provided on a front surface 100b (see FIG. 6) side of the semiconductor substrate.

First, a planar configuration of the pixel 10a will be described with reference to FIG. 5. FIG. 5 illustrates a case where the back surface 100a of the semiconductor substrate 100 is seen from above as described earlier, and illustrates a state in which four pixels 10a are arranged in a 2×2 layout, and in FIG. 5, illustration of an on-chip lens 140 (see FIG. 6) is omitted. Specifically, the pixels 10a are formed in a lattice shape, and in other words, the pixels 10a are separated by a pixel separation portion (pixel separation wall) 120 having a substantially rectangular frame shape surrounding the pixels 10a. A hole accumulation region 108 is provided inside each pixel separation portion 120 along the pixel separation portion 120. Further, at the center of each pixel 10a, an n-type semiconductor region 106 forming an avalanche multiplication region (multiplication region) is provided.

Next, a cross-sectional configuration of the pixel 10a will be described with reference to FIG. 6. Specifically, in the cross-sectional view of the pixel 10a illustrated in FIG. 6, a structure mainly related to the semiconductor substrate 100 is illustrated, the lower part of FIG. 6 corresponds to a back surface 102a side of the semiconductor substrate 100, and the on-chip lens 140 and the like are formed on the back surface 102a. The back surface 100a serves as a light-receiving surface on which reflected light reflected from the subjects 612 and 613 is incident. On the other hand, the upper part of FIG. 6 corresponds to the front surface 100b side of the semiconductor substrate 100, and although not illustrated, a wiring layer (not illustrated) including a circuit or the like that drives the pixel 10a is formed.

As illustrated in FIG. 6, the pixel 10a includes an n-type sub-region 102, a p-type semiconductor region 104, an n-type semiconductor region 106, a high-concentration n-type semiconductor region 106a, the hole accumulation region 108, and a high-concentration p-type semiconductor region 108a provided in an n-type semiconductor substrate 100 including a silicon substrate. The pixel 10a includes the pixel separation portion (pixel separation wall) 120 that surrounds the pixel 10a and isolates the subject pixel 10a from another adjacent pixel 10a. The pixel 10 also includes a cathode electrode 130 electrically connected to the high-concentration n-type semiconductor region 106a and an anode electrode 132 electrically connected to the high-concentration p-type semiconductor region 108a. Further, the pixel 10a includes the on-chip lens (lens unit) 140 on the back surface 100a of the semiconductor substrate 100.

The n-type sub-region (photoelectric conversion unit) 102 is a region having a low impurity concentration in the semiconductor substrate 100 having an n-type conductivity type, and the n-type sub-region 102 absorbs light, and generates an electric field that transfers electrons (electric charges) generated by photoelectric conversion to the avalanche multiplication region to be described later.

The p-type semiconductor region 104 and the n-type semiconductor region 106 are laminated on the n-type sub-region 102 in the semiconductor substrate 100 so as to form a PN junction. The avalanche multiplication region is formed by a depletion layer generated in the region where the p-type semiconductor region 104 and the n-type semiconductor region 106 are bonded. As described above, the valanche multiplication region can amplify electrons (electric charges). For example, the impurity concentration of the n-type sub-region 102 is preferably a low concentration of 1E+14/cm³ or less. This can improve the efficiency of light detection called photon detection efficiency (PDE). In addition, for example, the impurity concentration of each of the n-type semiconductor region 106 and the p-type semiconductor region 104 forming the avalanche multiplication region is preferably a high concentration of 1E+16/cm³ or more.

The n-type semiconductor region 106 has, at the upper center thereof, the high-concentration n-type semiconductor region 106a, which is a semiconductor region containing a high concentration of n-type impurities, formed at a predetermined depth from the front surface 100b of the semiconductor substrate 100. The high-concentration n-type semiconductor region 106a functions as a contact portion connected to the cathode electrode (cathode portion) 130 for supplying a negative voltage for forming an avalanche multiplication region. Therefore, the power supply voltage VE is applied from the cathode electrode 130 to the high-concentration n-type semiconductor region 106a.

The hole accumulation region 108 is a p-type semiconductor region formed so as to surround the outer surface of the n-type sub-region 102 and cover the inner surface of the pixel separation portion 120, and the hole accumulation region 108 can accumulate holes generated by photoelectric conversion. The hole accumulation region 108 also has an effect of trapping electrons generated at an interface with the pixel separation portion 120 to be described later and reducing a dark count rate (DCR). The hole accumulation region 108 is provided on the side surface of the n-type sub-region 102, which forms a lateral electric field to collect electrons (electric charges) in the high electric field region more easily, resulting in the improvement in PDE.

The high-concentration p-type semiconductor region 108a having a high p-type impurity concentration is provided in a region, near the front surface 100b of the semiconductor substrate 100, of the hole accumulation region 108. The high-concentration p-type semiconductor region 108a functions as a contact portion connected to the anode electrode (anode portion) 132. Therefore, the power supply voltage VCC is applied from the anode electrode 132 to the high-concentration p-type semiconductor region 108a. The cathode electrode 130 and the anode electrode 132 described above are provided on the front surface (second surface) 100b of the semiconductor substrate 100 via an insulating film (not illustrated), and the cathode electrode 130 and the anode electrode 132 are preferably formed of a metal or the like that reflects light. This allows the cathode electrode 130 and the anode electrode 132 to reflect light that is transmitted through the semiconductor substrate 100 and emitted to the outside from the front surface 100b of the semiconductor substrate 100 into the semiconductor substrate 100; therefore, the photon detection efficiency (PDE) of the pixel 10a can be improved. In short, the cathode electrode 130 and the anode electrode 132 can function as a reflective portion (second reflective portion) that reflects light. It is not always necessary to provide the reflective portion that reflects light emitted to the outside from the front surface 100b of the semiconductor substrate 100 into the semiconductor substrate 100 as the cathode electrode 130 and the anode electrode 132, that is, the reflective portion may be provided as a functional portion only performing reflection.

The pixel separation portion (pixel separation wall) 120 that isolates the pixels 10a from one another is provided at a pixel boundary portion of the subject pixel 10a which is a boundary with the adjacent pixel 10a. For example, the pixel separation portion 120 may have a double structure in which the outer side (the n-type sub-region 102 side) of a metal film such as tungsten (W) is covered with an insulating film such as a silicon oxide film and a barrier metal film. The pixel separation portion 120 and the hole accumulation region 108 are provided, which reduces electrical and optical crosstalk between the pixels 10a.

The pixel 10a has been described as having a structure of reading out electrons as signal electric charges (electric charges), but the structure is not limited thereto, and the pixel 10a may have a structure of reading out holes. In this case, each semiconductor region of the pixel 10a has a conductivity type in which the above-described conductivity type is inverted.

<1.5 Background>

Next, based on the configuration of the pixel 10a according to the comparative example, details of the background in which the inventors have created the embodiments of the present disclosure will be described with reference to FIG. 6. In the pixel 10a according to the comparative example, as illustrated in FIG. 6, the cathode electrode 130 and the anode electrode 132 are formed of a metal or the like that reflects light, so that light transmitted through the semiconductor substrate 100 is reflected into the semiconductor substrate 100. Such a configuration enables, in the pixel 10a, the light transmitted through the semiconductor substrate 100 to be absorbed again by the photodiode 20 in the semiconductor substrate 100, resulting in the improvement in PDE of the pixel 10a. That is, in the pixel 10a according to the comparative example, the reflective portion that reflects light is provided on the front surface 100b side of the semiconductor substrate 100, so that the light transmitted through the semiconductor substrate 100 can be reflected into the semiconductor substrate 100 by the reflective portion, so that the photon detection efficiency (PDE) of the pixel 10a can be improved.

However, the pixel 10a according to the comparative example has no reflective portion that reflects the light as described above on the back surface 100a side of the semiconductor substrate 100, and thus the light emitted from the back surface 100a to the outside cannot be made incident again on the inside of the semiconductor substrate 100. Therefore, in the pixel 10a according to the comparative example, the incident light cannot be sufficiently used and thus there is a limit to improvement in photon detection efficiency (PDE).

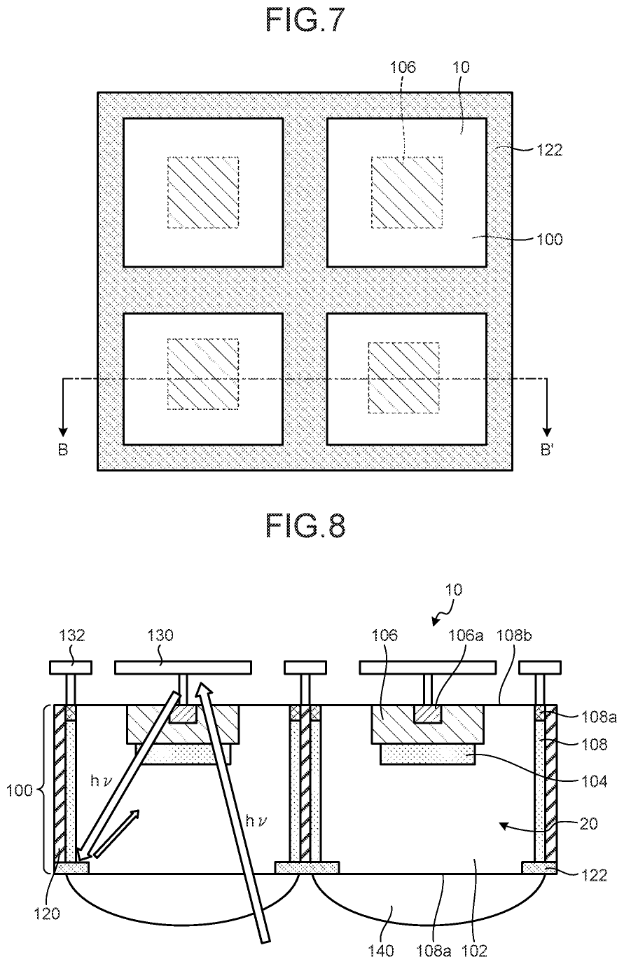

In view of the above-described situation, the inventors have intensively studied the configuration of the pixel 10a in order to further improve the photon detection efficiency, and have created the first embodiment of the present disclosure described below. The pixel 10a according to the comparative example has the reflective portion that reflects light only on the front surface 100b side of the semiconductor substrate 100; however, in the pixel 10 (see FIG. 7) according to the first embodiment of the present disclosure created by the inventors, a reflective portion 122 (See FIGS. 7 and 8) reflecting light is provided also on the back surface 100a side of the semiconductor substrate 100. Specifically, in the present embodiment, the reflective portion 122 reflecting light is provided not only on the front surface 100b side of the semiconductor substrate 100 but also on the back surface 100a side thereof, and thus the light emitted from the back surface 100a to the outside can be reflected into the semiconductor substrate 100. Further, in the present embodiment, it is necessary to cause light to enter the photodiode 20 in the semiconductor substrate 100, and thus, in order to provide the reflective portion 122 also on the back surface 100a side without blocking such a light path, the reflective portion 122 is provided so as to slightly extend (protrude) from the pixel separation portion 120. As a result, in the present embodiment, the light emitted from the back surface 100a to the outside can be reflected into the semiconductor substrate 100; therefore, the photodiode 20 can absorb the light again, resulting in further improvement in photon detection efficiency (PDE) of the pixel 10. Hereinafter, details of such a first embodiment of the present disclosure will be sequentially described.

### 2. FIRST EMBODIMENT

<2.1 Planar Configuration>

First, details of a planar configuration of a pixel 10 according to the first embodiment of the present disclosure created by the inventors will be described with reference to FIG. 7. FIG. 7 is a schematic plan view illustrating an example of a detailed configuration of the pixel 10 according to the present embodiment. Specifically, FIG. 7 illustrates a plane of a pixel array unit 512 in which four pixels 10 are arranged in a 2×2 matrix when seen from above the back surface (first surface) 100a of the semiconductor substrate 100, and illustration of an on-chip lens 140 (see FIG. 8) is omitted. In FIG. 7, the positional relationship of the constituent elements is schematically illustrated for easy understanding, and the configuration of FIG. 7 may be different from the actual detailed configuration.

Specifically, in the present embodiment, as illustrated in FIG. 7, the pixels 10 are formed in a lattice shape, and in other words, the pixels 10a are separated from one another by a pixel separation portion (pixel separation wall) 120 having a substantially rectangular frame shape surrounding the pixels 10a. Further, in the present embodiment, the reflective portion (first reflective portion) 122 is provided on the pixel separation portion 120. Specifically, the reflective portion 122 is provided so as to extend (protrude) from the pixel separation portion 120 toward the center of the pixel 10. In other words, the width of the reflective portion 122 is larger than the width of the pixel separation portion 120. Therefore, the pixel separation portion 120 is not illustrated in FIG. 7 because it is blocked by the reflective portion 122. The reflective portion 122 can reflect light emitted to the outside from the back surface 100a of the semiconductor substrate 100 into the semiconductor substrate 100. As a result, in the present embodiment, the light emitted from the back surface 100a to the outside can be absorbed again by the photodiode 20 inside the semiconductor substrate 100, resulting in further improvement in photon detection efficiency (PDE) of the pixel 10. Note that, in the present embodiment, the reflective portion 122 is not limited to being provided so as to extend from all the contour lines of the pixel separation portion (pixel separation wall) 120, and it is only required that the reflective portion 122 is provided so as to extend from at least some of the contour lines.

Further, in the present embodiment, at the center of each pixel 10, an n-type semiconductor region 106 forming an avalanche multiplication region (multiplication region) is provided. The reflective portion 122 is provided so as not to overlap with the n-type semiconductor region 106, and thus the reflective portion 122 does not block light entering from the back surface 100a to the photodiode (photoelectric conversion unit) 20 (see FIG. 8) located at the center of the pixel 10 while reflecting light emitted from the back surface 100a to the outside.

That is, in the present embodiment, the width of the reflective portion 122 is not particularly limited as long as the reflective portion 122 has a width enough to reflect light emitted to the outside of the pixel 10 (semiconductor substrate 100) to reach the inside while securing incidence of light to the pixel 10 (into the semiconductor substrate 100).

<2.2 Cross-Sectional Configuration>

Next, the cross-sectional configuration of the pixel 10 according to the present embodiment will be described in detail with reference to FIG. 8. FIG. 8 is a schematic cross-sectional view illustrating an example of a detailed configuration of the pixel 10 according to the present embodiment, and specifically illustrates a cross section taken along a line B-B′ illustrated in FIG. 7. In FIG. 8, the positional relationship of the constituent elements is schematically illustrated for easy understanding, and the cross section in FIG. 8 may be different from the actual cross section.

In the following description, it is assumed that the pixel 10 is a back-illuminated pixel 10 on which light (indicated by an arrow in the drawing) is incident from the lower surface (back surface 100a) side in FIG. 8. However, the pixel 10 is not limited to the back-illuminated pixel, and may be a front-illuminated pixel 10 on which light is incident via a wiring layer (not illustrated) provided on the front surface 100b side of the semiconductor substrate 100.

As illustrated in FIG. 8, in the present embodiment, the pixel 10 includes an n-type sub-region 102, a p-type semiconductor region 104, an n-type semiconductor region 106, a high-concentration n-type semiconductor region 106a, a hole accumulation region 108, and a high-concentration p-type semiconductor region 108a provided in an n-type semiconductor substrate 100 including a silicon substrate, as with the pixel 10a according to the comparative example. The pixel 10 includes the pixel separation portion (pixel separation wall) 120 that surrounds the pixel 10 and isolates the subject pixel 10 from another adjacent pixel 10. The pixel 10 also includes a cathode electrode 130 electrically connected to the high-concentration n-type semiconductor region 106a and an anode electrode 132 electrically connected to the high-concentration p-type semiconductor region 108a. Further, the pixel 10 includes the on-chip lens (lens unit) 140 on the back surface 100a of the semiconductor substrate 100.

The n-type sub-region (photoelectric conversion unit) 102 is a region having a low impurity concentration in the semiconductor substrate 100 having an n-type conductivity type, and as the photodiode 20, the n-type sub-region 102 absorbs light, and generates an electric field that transfers electrons (electrons) generated by photoelectric conversion to the avalanche multiplication region to be described later.

The p-type semiconductor region 104 containing a p-type conductivity type (first conductivity type) impurity and the n-type semiconductor region 106 containing an n-type conductivity type (second conductivity type) impurity are laminated on the n-type sub-region 102 in the semiconductor substrate 100 so as to form a PN junction. The avalanche multiplication region (multiplication region) is formed by a depletion layer generated in the region where the p-type semiconductor region 104 and the n-type semiconductor region 106 are bonded. For example, the impurity concentration of the n-type sub-region 102 is preferably a low concentration of 1E+14/cm³ or less. This can improve the efficiency of light detection called photon detection efficiency (PDE). In addition, for example, the impurity concentration of each of the n-type semiconductor region 106 and the p-type semiconductor region 104 forming the avalanche multiplication region is preferably a high concentration of 1E+16/cm³ or more.

The n-type semiconductor region 106 has, at the upper center thereof, the high-concentration n-type semiconductor region 106a, which is a semiconductor region containing a high concentration of n-type impurities, formed at a predetermined depth from the front surface 100b of the semiconductor substrate 100. The high-concentration n-type semiconductor region 106a functions as a contact portion connected to the cathode electrode (cathode portion) 130 for supplying a negative voltage for forming an avalanche multiplication region.

The hole accumulation region 108 is a p-type semiconductor region formed so as to surround the outer surface of the n-type sub-region 102 and cover the inner surface of the pixel separation portion (pixel separation wall) 120, and the hole accumulation region 108 can accumulate holes generated by photoelectric conversion. The hole accumulation region 108 also has an effect of trapping electrons generated at an interface with the pixel separation portion 120 and reducing a DCR.

The high-concentration p-type semiconductor region 108a having a high impurity concentration is provided in a region, near the front surface 100b of the semiconductor substrate 100, of the hole accumulation region 108. The high-concentration p-type semiconductor region 108a functions as a contact portion connected to the anode electrode (anode portion) 132. The cathode electrode 130 and the anode electrode 132 are provided on the front surface (second surface) 100b of the semiconductor substrate 100 via an insulating film (not illustrated), and the cathode electrode 130 and the anode electrode 132 are preferably formed of a metal or the like that reflects light. This allows the cathode electrode 130 and the anode electrode 132 to reflect light that is transmitted through the semiconductor substrate 100 and emitted to the outside from the front surface 100b into the semiconductor substrate 100; therefore, the photon detection efficiency (PDE) of the pixel 10 can be improved. In short, the cathode electrode 130 and the anode electrode 132 can function as a reflective portion (second reflective portion) that reflects light. In the present embodiment, it is not always necessary to provide the reflective portion that reflects light emitted to the outside from the front surface 100b of the semiconductor substrate 100 into the semiconductor substrate 100 as the cathode electrode 130 and the anode electrode 132, that is, the reflective portion may be provided as a functional portion only performing reflection.

In the present embodiment also, the pixel separation portion (pixel separation wall) 120 that isolates the pixels 10a from one another is provided at a pixel boundary portion of the subject pixel 10 which is a boundary with the adjacent pixel 10. The pixel separation portion 120 is formed of, for example, a metal film of tungsten (W), aluminum (Al), titanium (Ti), titanium nitride (TiN), tungsten nitride (WN), or the like, or a laminated film thereof. Alternatively, the pixel separation portion 120 may have a double structure in which the outer side (the n-type sub-region 102 side) of a metal film such as tungsten is covered with an insulating film such as a silicon oxide film and a barrier metal film. The pixel separation portion 120 and the hole accumulation region 108 are provided, which reduces electrical and optical crosstalk between the pixels 10.

Further, in the present embodiment, as described above, the reflective portion (first reflective portion) 122 is provided on the back surface 100a side of the pixel separation portion 120 and the hole accumulation region 108. Specifically, the reflective portion 122 is provided so as to protrude from the pixel separation portion 120 toward the center of the pixel 10. In other words, the width of the reflective portion 122 is larger than the width of the pixel separation portion 120. Further, in the present embodiment, the reflective portion 122 is provided without overlapping with the n-type semiconductor region 106 forming an avalanche multiplication region (multiplication region). That is, in the present embodiment, the width of the reflective portion 122 (width of the reflective portion 122 in the cross-sectional view of FIG. 8) is not particularly limited as long as the reflective portion 122 has a width enough to reflect light emitted from the back surface 100a to the outside of the semiconductor substrate 100 to reach the inside while securing incidence of light to the n-type sub-region 102 in the semiconductor substrate 100. Further, in the present embodiment, similarly to the pixel separation portion 120, the reflective portion 122 is preferably formed of, for example, a metal film of tungsten (W), aluminum (Al), titanium (Ti), titanium nitride (TiN), or tungsten nitride (WN), or a laminated film thereof, and the number of manufacturing steps can be reduced by using the same material as that of the pixel separation portion 120. In the present embodiment, the film thickness of the reflective portion 122 is, for example, about 500 nm to 600 nm, and is not particularly limited as long as the reflective portion 122 has a film thickness enough to reflect light.

As described above, the reflective portion 122 as described above is provided in the present embodiment, which enables light (indicated by an arrow in FIG. 8) emitted to the outside from the back surface 100a to be reflected into the semiconductor substrate 100. As a result, in the present embodiment, the light emitted from the back surface 100a to the outside can be absorbed again by the photodiode 20 inside the semiconductor substrate 100. In the present embodiment, the reflective portion 122 is provided so as not to overlap with the n-type semiconductor region 106, and thus the reflective portion 122 does not block light entering from the back surface 100a to the photodiode 20 located at the center of the pixel 10. In short, in the present embodiment, the reflective portion 122 can reflect the light emitted to the outside from the back surface 100a into the semiconductor substrate 100 without blocking the incidence of the light, resulting in further improvement in photon detection efficiency (PDE) of the pixel 10.

The pixel 10 has been described as having a structure of reading out electrons as signal electric charges (electric charges), but the structure is not limited thereto, and the pixel 10 may have a structure of reading out holes. In this case, each semiconductor region of the pixel 10 has a conductivity type in which the above-described conductivity type is inverted.

### 3. SECOND EMBODIMENT

<3.1 Planar Configuration>

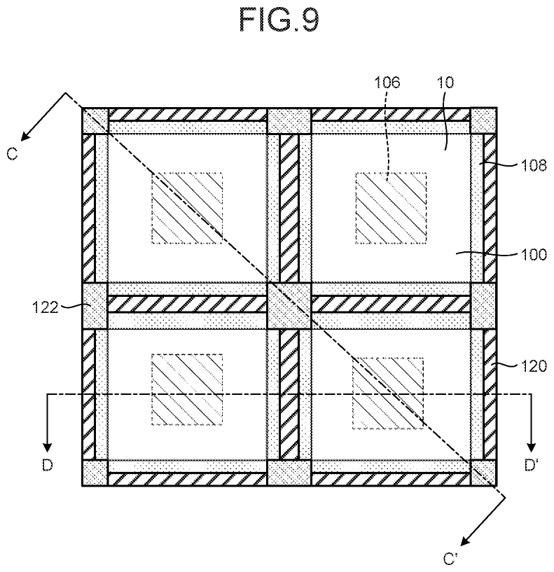

Next, the planar configuration of a pixel 10 according to the second embodiment of the present disclosure will be described in detail with reference to FIG. 9. FIG. 9 is a schematic plan view illustrating an example of a detailed configuration of the pixel 10 according to the present embodiment. Specifically, FIG. 9 illustrates a plane of a pixel array unit 512 in which four pixels 10 are arranged in a 2×2 matrix when seen from above the back surface (first surface) 100a of the semiconductor substrate 100, and illustration of an on-chip lens 140 is omitted. In FIG. 9, the positional relationship of the constituent elements is schematically illustrated for easy understanding, and the configuration of FIG. 9 may be different from the actual detailed configuration.

Specifically, in the present embodiment, as illustrated in FIG. 9, the reflective portions 122 are provided at positions of four corners of the pixel separation portion (pixel separation wall) 120 formed in a lattice shape. In the present embodiment, this makes it possible to reflect the light emitted to the outside from the back surface 100a into the semiconductor substrate 100 while preventing the interference of the light from entering the photodiode 20 located at the center of the pixel 10 from the back surface 100a. As a result, according to the present embodiment, the photon detection efficiency (PDE) of the pixel 10 can be further improved. Note that, in the present embodiment, the reflective portion 122 is not limited to being provided at each of four corners of the pixel separation portion (pixel separation wall) 120, and it is only required that the reflective portion 122 is provided in at least one of the four corners. In the present embodiment, the size of the reflective portion 122 is not particularly limited as long as the reflective portion 122 has a size enough to reflect light emitted to the outside of the pixel 10 (semiconductor substrate 100) to reach the inside while securing incidence of light to the pixel 10 (into the semiconductor substrate 100).

<3.2 Cross-Sectional Configuration>

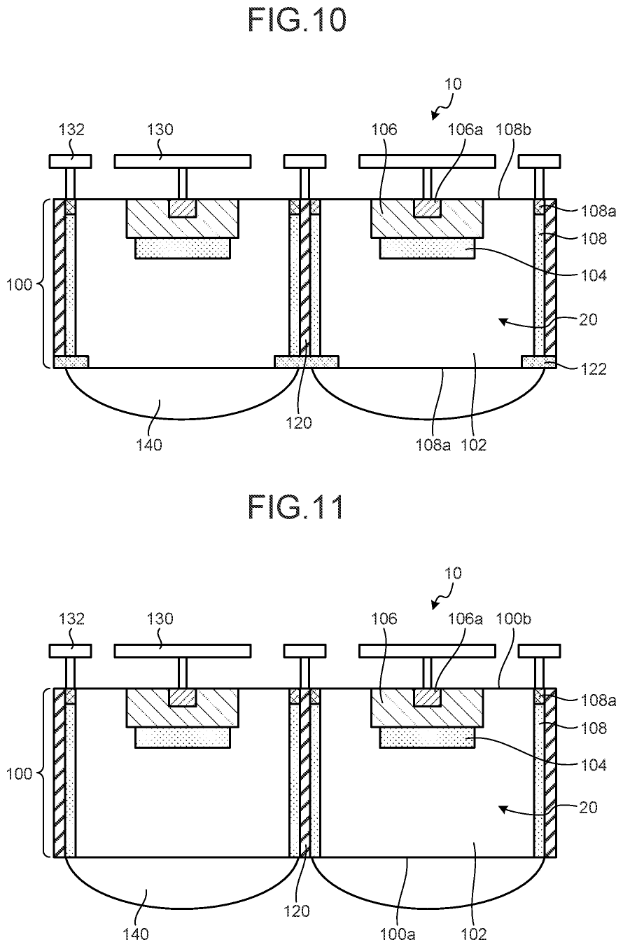

Next, the cross-sectional configuration of the pixel 10 according to the present embodiment will be described in detail with reference to FIGS. 10 and 11. FIG. 10 is a schematic cross-sectional view illustrating an example of a detailed configuration of the pixel 10 according to the present embodiment, and specifically illustrates a cross section taken along a line C-C′ illustrated in FIG. 9. FIG. 11 is a schematic cross-sectional view illustrating an example of a detailed configuration of the pixel 10 according to the present embodiment, and specifically illustrates a cross section taken along a line D-D′ illustrated in FIG. 9. In FIGS. 10 and 11, the positional relationship of the constituent elements is schematically illustrated for easy understanding, and the cross section in FIGS. 10 and 11 may be different from the actual cross section.

In the present embodiment, as illustrated in FIG. 10, the reflective portion (first reflective portion) 122 is provided on the back surface 100a side of four corners of the pixel separation portion (pixel separation wall) 120. The size of the reflective portion 122 is larger than that of an intersection portion of the pixel separation portion 120. Further, in the present embodiment, the reflective portion 122 is provided without overlapping with the n-type semiconductor region 106 forming an avalanche multiplication region (multiplication region). Further, in the present embodiment, as illustrated in FIG. 11, the reflective portion (first reflective portion) 122 is not provided on the back surface 100a side of a side portion of the pixel separation portion 120.

As described above, in the present embodiment, the reflective portions 122 are provided at positions of four corners of the pixel separation portion 120 formed in a lattice shape. In the present embodiment, this makes it possible to reflect the light emitted to the outside from the back surface 100a into the semiconductor substrate 100 while preventing the interference of the light from entering the photodiode 20 located at the center of the pixel 10 from the back surface 100a. As a result, according to the present embodiment, the photon detection efficiency (PDE) of the pixel 10 can be further improved.

### 4. THIRD EMBODIMENT

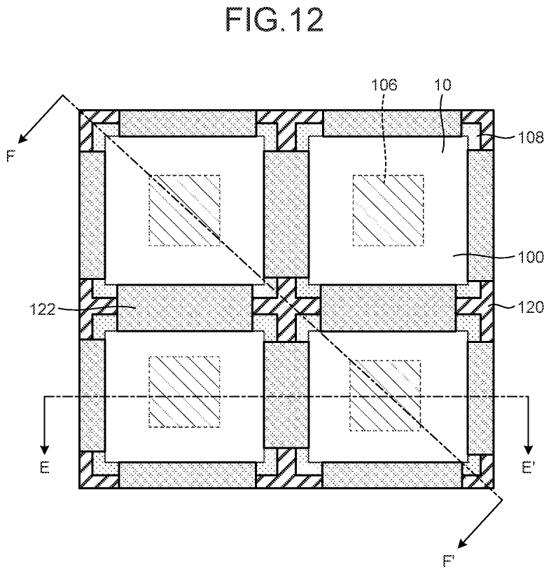

Next, the planar configuration of a pixel 10 according to the third embodiment of the present disclosure will be described in detail with reference to FIG. 12. FIG. 12 is a schematic plan view illustrating an example of a detailed configuration of the pixel 10 according to the present embodiment. Specifically, FIG. 12 illustrates a plane of a pixel array unit 512 in which four pixels 10 are arranged in a 2×2 matrix when seen from above the back surface (first surface) 100a of the semiconductor substrate 100, and illustration of an on-chip lens 140 is omitted. In FIG. 12, the positional relationship of the constituent elements is schematically illustrated for easy understanding, and the configuration of FIG. 12 may be different from the actual detailed configuration.

Specifically, in the present embodiment, as illustrated in FIG. 9, the reflective portions 122 are provided so as to extend (protrude) from the pixel separation portion (pixel separation wall) 120 toward the center of the pixel 10 at positions of side portions of the pixel separation portion 120 formed in a lattice shape. Further, in the present embodiment, the reflective portion 122 is not provided at positions of four corners of the pixel separation portion 120. In the present embodiment, this makes it possible to reflect the light emitted to the outside from the back surface 100a into the semiconductor substrate 100 while preventing the interference of the light from entering the photodiode 20 located at the center of the pixel 10 from the back surface 100a. As a result, according to the present embodiment, the photon detection efficiency (PDE) of the pixel 10 can be further improved. Note that, in the present embodiment, the reflective portion 122 is not limited to being provided at each of four side portions of the pixel separation portion (pixel separation wall) 120, and it is only required that the reflective portion 122 is provided in at least one of the four side portions. Furthermore, in the present embodiment, the width of the reflective portion 122 is not particularly limited as long as the reflective portion 122 has a width enough to reflect light emitted to the outside of the pixel 10 (semiconductor substrate 100) to reach the inside while securing incidence of light to the pixel 10 (into the semiconductor substrate 100).

In the present embodiment, the cross section taken along a line E-E′ in FIG. 12 corresponds to FIG. 10, and the cross section taken along a line F-F′ in FIG. 12 corresponds to FIG. 11; therefore, the description of the cross-sectional configuration of the pixel 10 according to the present embodiment is omitted.

As described above, in the present embodiment, the reflective portions 122 are provided at positions of four side portions of the pixel separation portion 120 formed in a lattice shape. In the present embodiment, this makes it possible to reflect the light emitted to the outside from the back surface 100a into the semiconductor substrate 100 while preventing the interference of the light from entering the photodiode 20 located at the center of the pixel 10 from the back surface 100a. As a result, according to the present embodiment, the photon detection efficiency (PDE) of the pixel 10 can be further improved.

Note that the first to third embodiments of the present disclosure are preferably selected according to restrictions on the (chip) area in the semiconductor substrate 100 on which the pixels 10 are provided, characteristics required for the pixels 10, and the like.

### 5. FOURTH EMBODIMENT

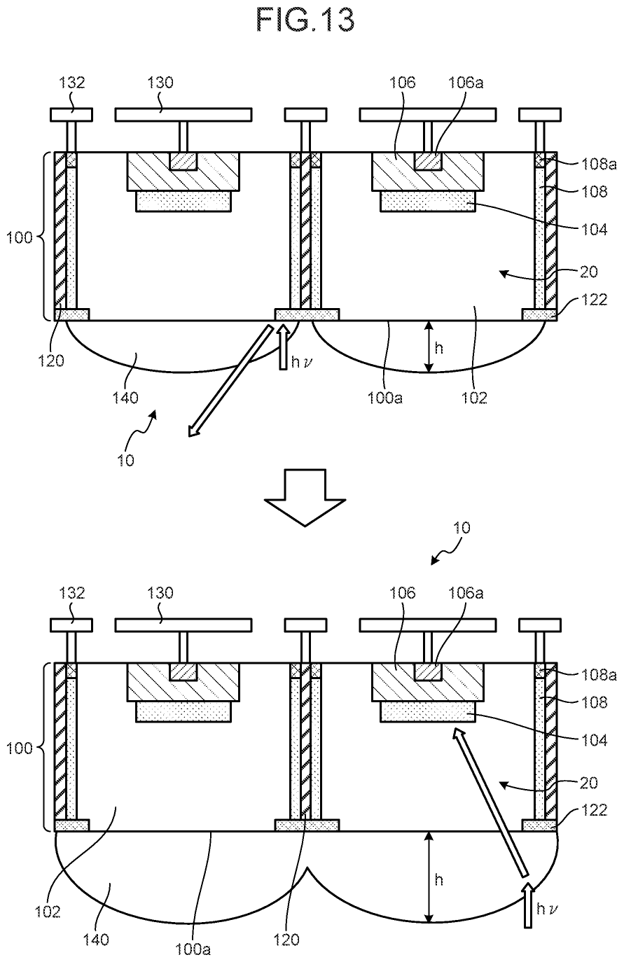

Next, the configuration of a pixel 10 according to the fourth embodiment of the present disclosure will be described in detail with reference to FIG. 13. FIG. 13 is an explanatory diagram for explaining the detailed configuration of the pixel 10 according to the present embodiment, and specifically, FIG. 13 is a schematic cross-sectional view illustrating an example of the detailed configuration of the pixel 10 according to the present embodiment.

For example, in a case where the height of the on-chip lens 140 is low, as illustrated in the upper part of FIG. 13, there is a case where light (indicated by an arrow in the drawing) entering from the back surface 100a side is reflected by the reflective portion 122 described so far, and cannot enter the photodiode 20 in the semiconductor substrate 100.

To address this, in the present embodiment, in order to prevent the reflective portion 122 from reflecting such light entering from the back surface 100a side, the on-chip lens (lens unit) 140 is adjusted so as to function to refract the light rather than reflecting the light. For example, as illustrated in the lower part of FIG. 13, the height of the on-chip lens 140 is increased, which makes it possible to prevent the reflective portion 122 from reflecting light entering from the back surface 100a side. As a result, in the present embodiment, the photon detection efficiency (PDE) of the pixel 10 can be further improved. The present embodiment is not limited to the adjustment to the height of the on-chip lens 140, and reflection, by the reflective portion 122, of light entering from the back surface 100a side may be prevented by changing the material forming the on-chip lens 140, or by adjusting the refractive index.

### 6. FIFTH EMBODIMENT

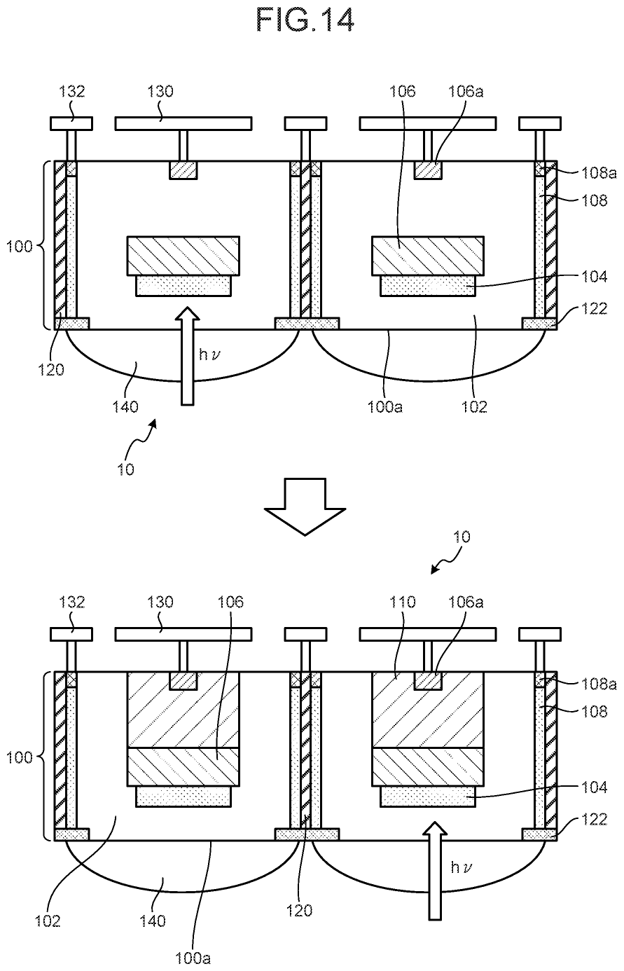

Next, the configuration of a pixel 10 according to the fifth embodiment of the present disclosure will be described in detail with reference to FIG. 14. FIG. 14 is an explanatory diagram for explaining the detailed configuration of the pixel 10 according to the present embodiment, and specifically, FIG. 14 is a schematic cross-sectional view illustrating an example of the detailed configuration of the pixel 10 according to the present embodiment.

Light entering the semiconductor substrate 100 from the back surface 100a is absorbed exponentially with respect to the depth of the back surface 100a of the semiconductor substrate 100. Therefore, for example, as illustrated on the upper part of FIG. 14, the p-type semiconductor region 104 and the n-type semiconductor region 106 forming an avalanche multiplication region (multiplication region) are provided on the back surface 100a side, which enables multiplying the generated electric charges more efficiently.

However, in the configuration illustrated on the upper part of FIG. 14, the n-type sub-region 102 between the high-concentration n-type semiconductor region 106a and the n-type semiconductor region 106 is likely to be depleted. As a result, in the configuration illustrated on the upper part of FIG. 14, it is difficult to efficiently apply a desired voltage from the cathode electrode 130 to the avalanche multiplication region via the high-concentration n-type semiconductor region 106a because the n-type sub-region 102 is likely to be depleted.

To address this, in the present embodiment, as illustrated on the lower part of FIG. 14, an n-type well region (third semiconductor region) 110 having n-type conductivity (second conductivity type) is provided between the high-concentration n-type semiconductor region 106a and the n-type semiconductor region 106. In the present embodiment, the impurity concentration of the n-type well region 110 is preferably lower than that of the n-type semiconductor region 106 and preferably higher than that of the n-type sub-region 102. In the present embodiment, the thickness of the n-type well region 110 may be larger than that of the avalanche multiplication region (multiplication region) formed of the p-type semiconductor region 104 and the n-type semiconductor region 106. In the present embodiment, this makes it possible to prevent the tendency to deplete a space between the high-concentration n-type semiconductor region 106a and the n-type semiconductor region 106, and thus, in a case where a voltage is applied to the avalanche multiplication region from the cathode electrode 130 via the high-concentration n-type semiconductor region 106a, a desired voltage can be efficiently applied to the avalanche multiplication region.

That is, in the present embodiment, the p-type semiconductor region 104 and the n-type semiconductor region 106 forming the avalanche multiplication region are located on the back surface 100a side, and the n-type well region 110 having n-type conductivity is provided between the high-concentration n-type semiconductor region 106a and the n-type semiconductor region 106. In such a configuration, according to the present embodiment, the generated electric charges can be multiplied more efficiently, and, in a case where a voltage is applied to the avalanche multiplication region from the cathode electrode 130 via the high-concentration n-type semiconductor region 106a, a desired voltage can be efficiently applied to the increased avalanche multiplication region.

### 7. SIXTH EMBODIMENT

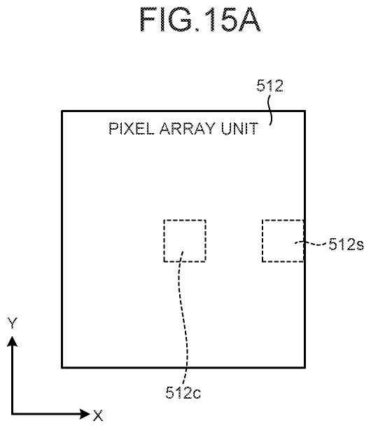

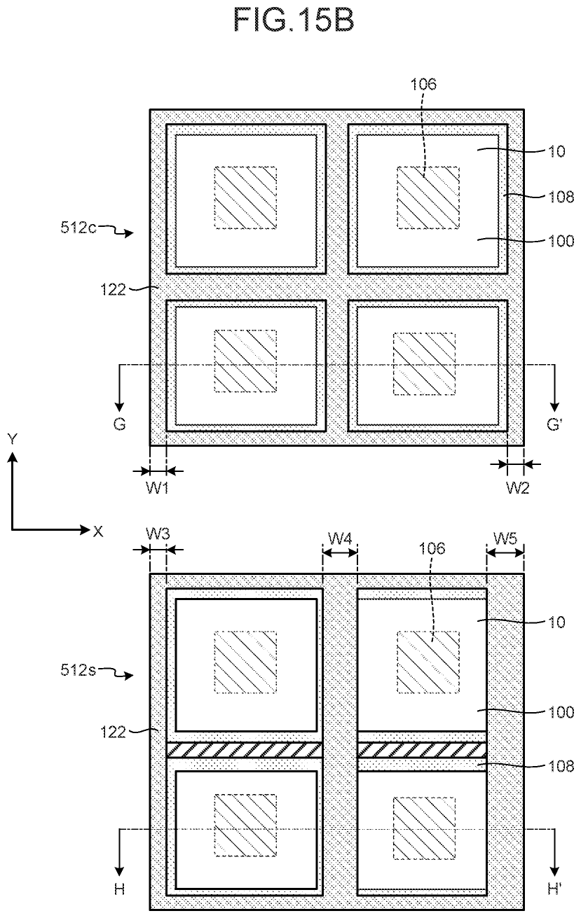

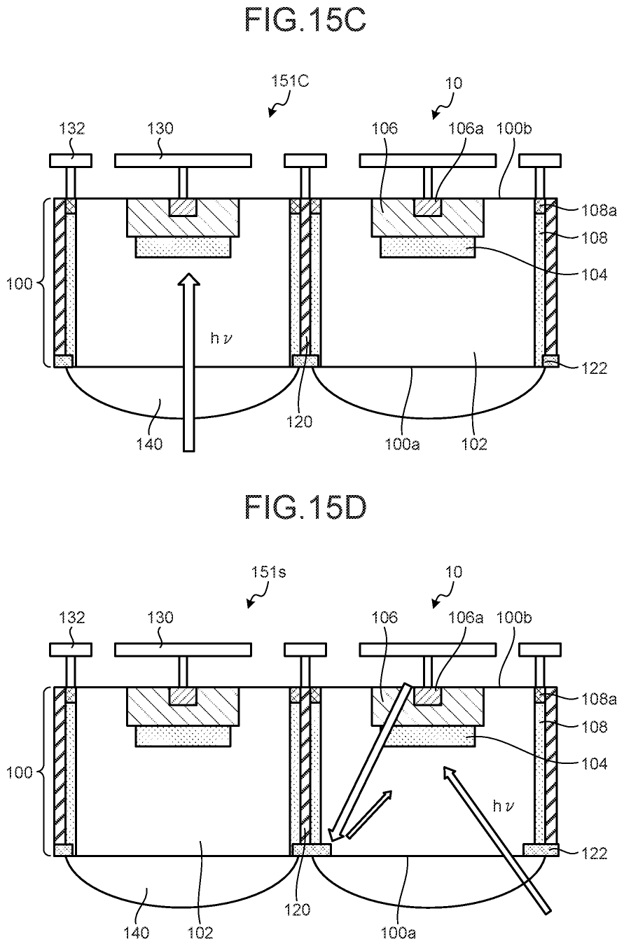

Next, the configuration of a pixel 10 according to the sixth embodiment of the present disclosure will be described in detail with reference to FIGS. 15A to 15D. FIG. 15A is a schematic plan view illustrating an example of a detailed configuration of a pixel array unit 512 according to the present embodiment. FIG. 15B is a schematic plan view illustrating an example of a detailed configuration of the pixel 10 according to the present embodiment. FIG. 15C is a schematic cross-sectional view illustrating an example of a detailed configuration of the pixel 10 according to the present embodiment, and specifically illustrates a cross section taken along a line G-G′ illustrated in FIG. 15B. FIG. 15D is a schematic cross-sectional view illustrating an example of a detailed configuration of the pixel 10 according to the present embodiment, and specifically illustrates a cross section taken along a line H-H′ illustrated in FIG. 15B.

In the meantime, the incident angle of light with respect to the pixel 10 changes depending on the position in the pixel array unit 512. In the present embodiment, the position and width of the reflective portion 122 (the degree of protrusion to the center of the pixel 10) are changed according to the position of the pixel 10 in the pixel array unit 512. According to the present embodiment, such a configuration enables the reflective portion 122 in each pixel 10 to reflect light emitted to the outside from the back surface 100a into the semiconductor substrate 100 without blocking the incidence of the light even if the positions in the pixel array unit 512 are different, resulting in further improvement in photon detection efficiency (PDE) of the pixel 10.

Specifically, as illustrated in FIG. 15-A, a central portion 512c and an end portion 512s of the pixel array unit 512 will be described separately.

First, in the central portion 512c of the pixel array unit 512 illustrated in the upper part of FIG. 15B, the reflective portion 122 is provided such that the position and widths (W1, W2) of the reflective portion 122 are uniform. On the other hand, in the end portion 512s of the pixel array unit 512 illustrated in the lower part of FIG. 15B, as the pixel array unit 512 extends away from the central portion 512c toward the end portion 512s along the X direction (first direction) in the drawing, the widths (distances) (W3, W4, W5) of the reflective portion 122 protruding from the pixel separation portion (pixel separation wall) 120 toward the center of the pixel 10 along the Y direction (second direction) in the drawing becomes longer. In short, in the present embodiment, the width and the degree of protrusion (shift amount) of the reflective portion 122 increase as the pixel array unit 512 extends toward the end thereof.

In this way, at the central portion 512c of the pixel array unit 512, as illustrated in FIG. 15C, light (indicated by an arrow in the drawing) perpendicularly incident on the back surface 100a can be efficiently absorbed by the semiconductor substrate 100 without being blocked by the reflective portion 122. On the other hand, at the end portion 512s of the pixel array unit 512, as illustrated in FIG. 15D, even in a case where light (indicated by an arrow in the drawing) obliquely incident on the back surface 100a is transmitted through the semiconductor substrate 100, reflected by the cathode electrode 130 or the like, and emitted to the outside of the semiconductor substrate 100, the light can be reflected by the wide reflective portion 122 and made incident into the semiconductor substrate 100 again.

That is, according to the present embodiment, such a configuration enables the reflective portion 122 in each pixel 10 to reflect light emitted to the outside from the back surface 100a into the semiconductor substrate 100 without blocking the incidence of the light even if the positions in the pixel array unit 512 are different, resulting in further improvement in photon detection efficiency (PDE) of the pixel 10.

Note that, the present embodiment is not limited to the configuration in which as the pixel array unit 512 extends away from the central portion 512c toward the end portion 512s along the X direction (first direction) in the drawing, the widths (distances) (W3, W4, W5) of the reflective portion 122 protruding from the pixel separation portion (pixel separation wall) 120 toward the center of the pixel 10 along the Y direction (second direction) in the drawing becomes longer. In the present embodiment, for example, another configuration is possible in which as the pixel array unit 512 extends away from the central portion 512c toward the end portion 512s along the Y direction (second direction) in the drawing, the widths (distances) (W3, W4, W5) of the reflective portion 122 protruding from the pixel separation portion (pixel separation wall) 120 toward the center of the pixel 10 along the X direction (first direction) in the drawing becomes longer. Alternatively, in the present embodiment, the above two configurations may be combined.

Further, in the present embodiment, the position or height of the on-chip lens 140 may be changed as the pixel array unit 512 extends toward the end thereof, as in the fifth embodiment.

### 8. SEVENTH EMBODIMENT

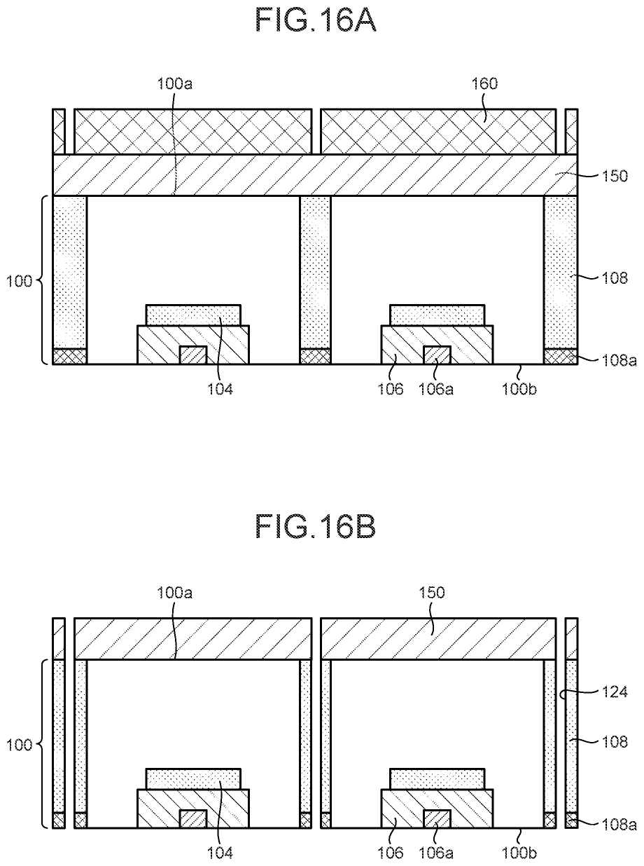

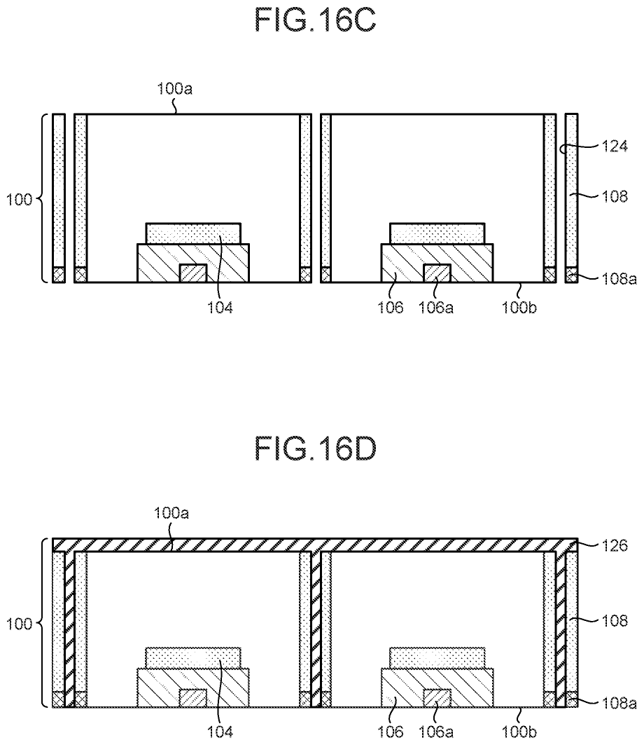

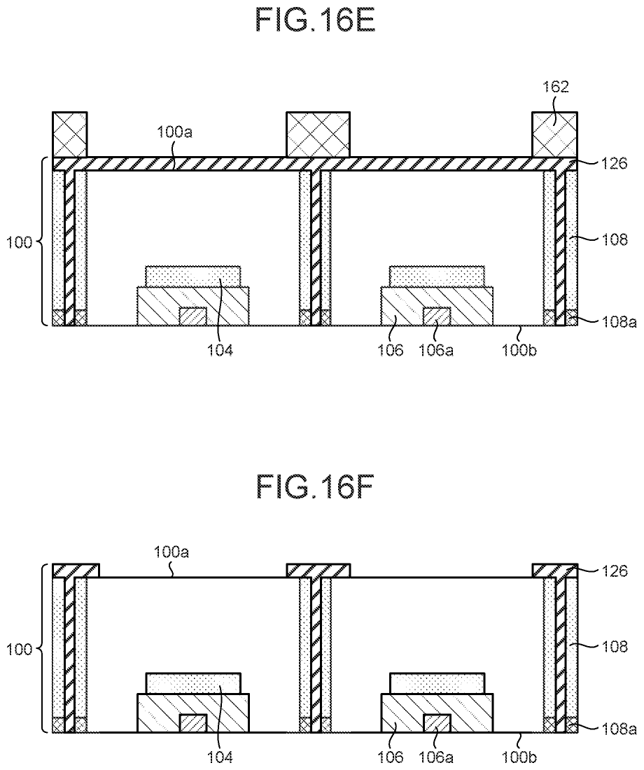

Next, a method for manufacturing a pixel 10 according to the present embodiment will be described with reference to FIGS. 16A to 16F. FIGS. 16A to 16F are schematic diagrams for explaining the method for manufacturing the pixel 10 according to the present embodiment, and specifically, each drawing is a cross-sectional view of the pixel 10 at each step in the manufacturing process. In each of the drawings, the upper part thereof corresponds to the back surface 100a side of the semiconductor substrate 100, and the lower part thereof corresponds to the front surface 100b side of the semiconductor substrate 100.

As illustrated in FIG. 16A, first, a mask material 150 is laminated on the back surface 100a of the semiconductor substrate 100 in which the p-type semiconductor region 104, the n-type semiconductor region 106, the high-concentration n-type semiconductor region 106a, the hole accumulation region 108, and the high-concentration p-type semiconductor region 108a are provided at predetermined positions. Further, a resist 160 having a predetermined pattern is formed on the mask material 150.

Next, as illustrated in FIG. 16B, trenches 124 penetrating the semiconductor substrate 100 from the back surface 100a to the front surface 100b are formed along the mask material 150 processed along the pattern of the resist 160.

Then, as illustrated in FIG. 16C, the mask material 150 is removed.

Further, an oxide film (not illustrated) and a barrier metal film (not illustrated) are formed so as to cover the bottom surface and the side walls of the trench 124. Then, as illustrated in FIG. 16D, a metal film 126 is formed so as to fill the trenches 124 and cover the back surface 100a of the semiconductor substrate 100.

Next, as illustrated in FIG. 16E, a resist 162 having a pattern is formed on the metal film 126.

Then, the metal film 126 is etched according to the pattern of the resist 162, so that a structure as illustrated in FIG. 16F can be obtained. Further, a plurality of films is laminated on the back surface 100a side of the semiconductor substrate 100 to form the on-chip lens 140, so that the pixel 10 according to the present embodiment can be obtained.

As described above, the pixel 10 according to the embodiments of the present disclosure can be easily and inexpensively manufactured using an existing semiconductor device manufacturing process.

### 9. SUMMARY

As described above, according to each embodiment of the present disclosure, the reflective portion 122 as described above is provided, which enables light emitted to the outside from the back surface 100a to be reflected into the semiconductor substrate 100. As a result, in each embodiment, the light emitted from the back surface 100a to the outside can be absorbed again by the photodiode 20 inside the semiconductor substrate 100. In each embodiment, the reflective portion 122 is provided so as not to overlap with the n-type semiconductor region 106, and thus the reflective portion 122 does not block light entering from the back surface 100a to the photodiode 20 located at the center of the pixel 10. In short, according to each embodiment of the present disclosure, the reflective portion 122 can reflect the light emitted to the outside from the back surface 100a into the semiconductor substrate 100 without blocking the incidence of the light, resulting in further improvement in photon detection efficiency (PDE) of the pixel 10.

In the embodiments of the present disclosure, the semiconductor substrate 100 is not necessarily a silicon substrate, and may be another substrate (for example, a silicon on insulator (SOI) substrate, a SiGe substrate, or the like). The semiconductor substrate 100 may have a configuration in which a semiconductor structure or the like is formed on such various substrates.

In the embodiments of the present disclosure, the conductivity types of the semiconductor substrate 100, each semiconductor region, and the like may be reversed, and for example, the present embodiment can be applied to the pixel 10 using holes as signal electric charges. In the embodiments of the present disclosure, the pixel 10 including the photodiode 20 in which the first conductivity type is p-type, the second conductivity type is n-type, and electrons are used as signal electric charges has been described, but the embodiments of the present disclosure are not limited to such an example. For example, the embodiments of the present disclosure can be applied to the pixel 10 having the photodiode 20 in which the first conductivity type is n-type, the second conductivity type is p-type, and holes are used as signal electric charges.

The pixel 10 according to the embodiments of the present disclosure is not limited to being applied to the photodetection device 501 applied to the distance measuring system 611. For example, the pixel 10 according to the embodiments of the present disclosure may be applied to an imaging device that captures an image as an image in which distribution of the amount of incident light of visible light is detected. For example, the present embodiment can be applied to an imaging device that captures distribution of incident amounts of infrared rays, X-rays, particles, or the like as an image, or an imaging device (physical amount distribution detection device) such as a fingerprint detection sensor that detects distribution of other physical amounts such as pressure and capacitance to capture the distribution thereof as an image.

In the embodiments of the present disclosure, examples of a method of forming each layer, each film, each element, and the like include a physical vapor deposition (PVD) method, a chemical vapor deposition (CVD) method, and the like. Examples of the PVD method include a vacuum vapor deposition method using resistance heating or high frequency heating, an electron beam (EB) vapor deposition method, various sputtering methods (magnetron sputtering method, radio frequency (RF)-direct current (DC) coupled bias sputtering method, electron cyclotron resonance (ECR) sputtering method, counter target sputtering method, high frequency sputtering method, and the like), an ion plating method, a laser ablation method, a molecular beam epitaxy (MBE) method, and a laser transfer method. Examples of the CVD method include a plasma CVD method, a thermal CVD method, a metal organic (MO)-CVD method, and a photo CVD method. Other methods include an electrolytic plating method, an electroless plating method, and a spin coating method; immersion method; cast method; micro-contact printing; drop cast method; various printing methods such as a screen printing method, an inkjet printing method, an offset printing method, a gravure printing method, and a flexographic printing method; stamping method; spray method; and various coating methods such as an air doctor coater method, a blade coater method, a rod coater method, a knife coater method, a squeeze coater method, a reverse roll coater method, a transfer roll coater method, a gravure coater method, a kiss coater method, a cast coater method, a spray coater method, a slit orifice coater method, and a calendar coater method. Examples of a patterning method of each layer include chemical etching such as shadow mask, laser transfer, and photolithography, and physical etching using ultraviolet rays, laser, or the like. In addition, examples of planarization technique include a chemical mechanical polishing (CMP) method, a laser planarization method, a reflow method, and the like. In essence, the pixel 10 according to the embodiments of the present disclosure can be easily and inexpensively manufactured using an existing semiconductor device manufacturing process.

Each step in the manufacturing method according to the embodiments of the present disclosure may not necessarily be processed in the described order. For example, the order of the steps may be changed appropriately and then performed. Further, the method used in each step may not necessarily be performed according to the described method, and may be performed by other methods.

### 10. APPLICATION EXAMPLE

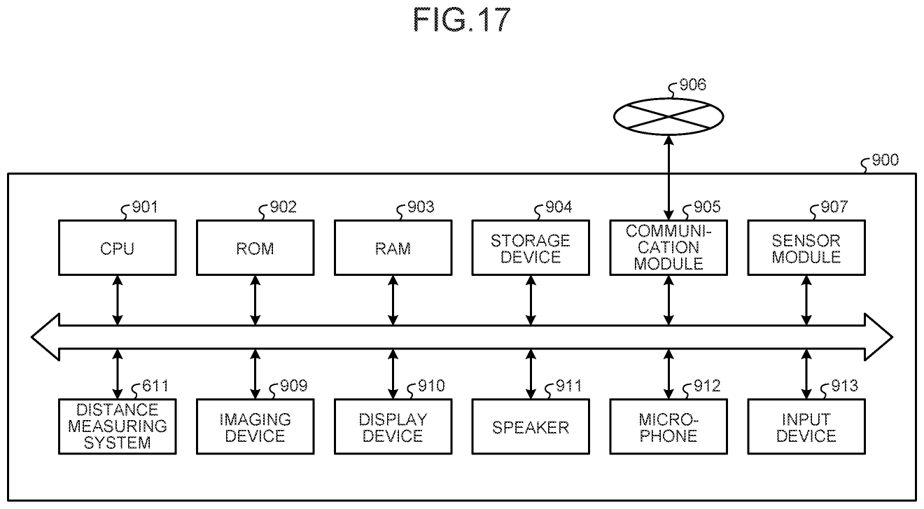

The distance measuring system 611 can be applied to various electronic devices such as a camera having a distance measuring function, a smartphone having a distance measuring function, and an industrial camera provided in a production line, for example. Accordingly, a configuration example of a smartphone 900 as an electronic device to which the present technology is applied will be described with reference to FIG. 17. FIG. 17 is a block diagram illustrating a configuration example of the smartphone 900 as an electronic device to which the distance measuring system 611 according to the embodiments of the present disclosure is applied.

As illustrated in FIG. 17, the smartphone 900 includes a central processing unit (CPU) 901, a read only memory (ROM) 902, and a random-access memory (RAM) 903. The smartphone 900 also includes a storage device 904, a communication module 905, and a sensor module 907. The smartphone 900 further includes the distance measuring system 611, and also includes an imaging device 909, a display device 910, a speaker 911, a microphone 912, an input device 913, and a bus 914. The smartphone 900 may include a processing circuit such as a digital signal processor (DSP) instead of or together with the CPU 901.

The CPU 901 functions as an arithmetic processing device and a control device, and controls the overall operation in the smartphone 900 or a part thereof according to various programs recorded in the ROM 902, the RAM 903, the storage device 904, or the like. The ROM 902 stores programs, operation parameters, and the like used by the CPU 901. The RAM 903 primarily stores programs used in the execution of the CPU 901, parameters that appropriately change in the execution, and the like. The CPU 901, the ROM 902, and the RAM 903 are connected to one another by the bus 914. The storage device 904 is a device for data storage configured as an example of a storage unit of the smartphone 900. The storage device 904 is implemented by, for example, a magnetic storage device such as a hard disk drive (HDD), a semiconductor storage device, an optical storage device, or the like. The storage device 904 stores programs and various data executed by the CPU 901, various data acquired from the outside, and the like.

The communication module 905 is a communication interface including, for example, a communication device for connecting to the communication network 906. The communication module 905 can be, for example, a communication card for wired or wireless local area network (LAN), Bluetooth (registered trademark), wireless USB (WUSB), or the like. The communication module 905 may be a router for optical communication, a router for asymmetric digital subscriber line (ADSL), a modem for various types of communication, or the like. The communication module 905 transmits and receives signals and the like to and from the Internet and other communication devices using a predetermined protocol such as TCP/IP. The communication network 906 connected to the communication module 905 is a network connected in a wired or wireless manner, and is, for example, the Internet, a home LAN, infrared communication, satellite communication, or the like.

The sensor module 907 includes, for example, various sensors such as a motion sensor (for example, an acceleration sensor, a gyro sensor, a geomagnetic sensor, or the like), a biometric sensor (for example, a pulse sensor, a blood pressure sensor, a fingerprint sensor, or the like), or a position sensor (for example, a global navigation satellite system (GNSS) receiver or the like).

The distance measuring system 611 is provided on the surface of the smartphone 900, and can acquire, for example, distances to and three-dimensional shapes of subjects 612 and 613 facing the surface of the smartphone 900 as a distance measurement result.

The imaging device 909 is provided on the surface of the smartphone 900, and can capture images of the subjects 612, 613, and the like located around the smartphone 900. Specifically, the imaging device 909 can be configured to include an imaging element (not illustrated) such as a complementary MOS (CMOS) image sensor, and a signal processing circuit (not illustrated) that performs imaging signal processing on a signal photoelectrically converted by the imaging element. The imaging device 909 may also include an optical system mechanism (not illustrated) including an imaging lens, a diaphragm mechanism, a zoom lens, and a focus lens, and a drive system mechanism (not illustrated) that controls the operation of the optical system mechanism. The imaging element collects incident light from the subjects 612, 613, and the like as an optical image, and the signal processing circuit photoelectrically converts the formed optical image in units of pixels, reads a signal of each pixel as an imaging signal, and performs image processing to acquire a captured image.

The display device 910 is provided on the surface of the smartphone 900, and can be, for example, a display device such as a liquid crystal display (LCD) or an organic electro luminescence (EL) display. The display device 910 can display an operation screen, a captured image acquired by the imaging device 909, and the like.

The speaker 911 can output, for example, a call voice, a voice accompanying a video content displayed by the display device 910 described above, and the like to a user.

The microphone 912 can collect, for example, a call voice of the user, a voice including a command to activate a function of the smartphone 900, and sound in a surrounding environment of the smartphone 900.

The input device 913 is a device operated by the user, such as a button, a keyboard, a touch panel, or a mouse. The input device 913 includes an input control circuit that generates an input signal based on information input by the user and outputs the input signal to the CPU 901. The user operates the input device 913, so that he/she can input various data to the smartphone 900 and instruct the smartphone 900 to perform a processing operation.

The configuration example of the smartphone 900 has been described above. Each of the constituent elements may be configured using a general-purpose member, or may be configured by hardware specialized for the function of each constituent element. Such a configuration can be appropriately changed according to the technical level at the time of implementation.

### 11. SUPPLEMENT

Although the preferred embodiments of the present disclosure have been described in detail with reference to the accompanying drawings, the technical scope of the present disclosure is not limited to such examples. It is obvious that a person having ordinary knowledge in the technical field of the present disclosure can conceive various changes or modifications within the scope of the technical idea described in the claims, and it is naturally understood that these also belong to the technical scope of the present disclosure.

The effects described in the present specification are merely illustrative or exemplary, and are not restrictive. That is, the technology according to the present disclosure can exhibit other effects obvious to those skilled in the art from the description of the present specification together with or instead of the above effects.

The present technology may also be configured as below.

(1) A photodetection device comprising:

a pixel array unit including a plurality of pixels that is arranged in a matrix on a semiconductor substrate to detect light, wherein

each of the pixels includes

a pixel separation wall that surrounds the pixels and separates the pixels from one another,

a photoelectric conversion unit that is provided inside the semiconductor substrate to generate an electric charge by light,

a multiplication region that is provided inside the semiconductor substrate to multiply the electric charge from the photoelectric conversion unit, and

first and second reflective portions that reflect light traveling toward outside the semiconductor substrate into the semiconductor substrate,

the first reflective portion is provided, on a first surface that receives light of the semiconductor substrate, to protrude from the pixel separation wall toward a pixel center, and

the second reflective portion is provided on a second surface of the semiconductor substrate facing the first surface.

(2) The photodetection device according to (1), wherein in a case where the semiconductor substrate is seen from above the first surface, a width of the first reflective portion is larger than a width of the pixel separation wall.
(3) The photodetection device according to (1) or (2), wherein in a case where the semiconductor substrate is seen from above the first surface, the first reflective portion is provided without overlapping with the multiplication region.
(4) The photodetection device according to any one of (1) to (3), wherein the first reflective portion includes at least one material selected from a group consisting of tungsten, aluminum, titanium, titanium nitride, and tungsten nitride.
(5) The photodetection device according to any one of (1) to (4), wherein in a case where the semiconductor substrate is seen from above the first surface, the pixel separation wall has a shape of a substantially rectangular frame surrounding each of the pixels.
(6) The photodetection device according to (5), wherein in a case where the semiconductor substrate is seen from above the first surface, the first reflective portion is located at four corners of the substantially rectangular frame.
(7) The photodetection device according to (5) or (6), wherein in a case where the semiconductor substrate is seen from above the first surface, the first reflective portion is located at four sides of the substantially rectangular frame.
(8) The photodetection device according to any one of (1) to (7), wherein each of the pixels includes, on the first surface, a lens unit that has a function to refract light from outside so as not to be reflected by the first reflective portion.
(9) The photodetection device according to (8), wherein

according to a distance from a center of the pixel array unit of each of the pixels,

a height of the lens unit with respect to the first surface is changed.

(10) The photodetection device according to any one of (1) to (9), wherein

the multiplication region includes

a first semiconductor region that is provided on the second surface side of the photoelectric conversion unit and contains a first conductivity type impurity, and

a second semiconductor region that is provided on the second surface side of the first semiconductor region and contains a second conductivity type impurity, the second conductivity type being a conductivity type opposite to the first conductivity type.

(11) The photodetection device according to (10), wherein

each of the pixels includes

a third semiconductor region that is provided on the second surface side of the second semiconductor region and contains the second conductivity type impurity, and

concentration of the impurity of the third semiconductor region is lower than that of the second semiconductor region.

(12) The photodetection device according to (11), wherein

the concentration of the impurity of the third semiconductor region is higher than that of the semiconductor substrate.

(13) The photodetection device according to (11) or (12), wherein the third semiconductor region is thicker than the multiplication region.
(14) The photodetection device according to any one of (1) to (13), wherein the second reflective portion includes a cathode portion that is electrically connected to the multiplication region.
(15) The photodetection device according to (14), wherein

each of the pixels includes a hole accumulation region that covers an inner surface of the pixel separation wall.

(16) The photodetection device according to (15), wherein the second reflective portion includes an anode portion that is provided on the second surface side of the hole accumulation region.
(17) The photodetection device according to (7), wherein

as the pixel array unit extends away from a center thereof toward an end portion thereof along a first direction,

a distance protruding from the pixel separation wall toward the pixel center along a second direction perpendicular to the first direction becomes longer.

(18) The photodetection device according to (17), wherein

as the pixel array unit extends away from the center thereof toward the end portion thereof along the second direction,

the distance protruding from the pixel separation wall toward the pixel center along the first direction becomes longer.

(19) An electronic device mounting a photodetection device, the photodetection device including

a pixel array unit including a plurality of pixels that is arranged in a matrix on a semiconductor substrate to detect light, wherein

each of the pixels includes

a pixel separation wall that surrounds the pixels and separates the pixels from one another,

a photoelectric conversion unit that is provided inside the semiconductor substrate to generate an electric charge by light,

a multiplication region that is provided inside the semiconductor substrate to multiply the electric charge from the photoelectric conversion unit, and

first and second reflective portions that reflect light traveling toward outside the semiconductor substrate into the semiconductor substrate,

the first reflective portion is provided, on a first surface that receives light of the semiconductor substrate, to protrude from the pixel separation wall toward a pixel center, and

the second reflective portion is provided on a second surface of the semiconductor substrate facing the first surface.

(20) A distance measuring system comprising:

an illumination device that emits irradiation light; and

a photodetection device that receives reflected light obtained by reflecting the irradiation light being reflected by a subject, wherein

the photodetection device includes

a pixel array unit including a plurality of pixels that is arranged in a matrix on a semiconductor substrate to detect light,

each of the pixels includes

a pixel separation wall that surrounds the pixels and separates the pixels from one another,

a photoelectric conversion unit that is provided inside the semiconductor substrate to generate an electric charge by light,

a multiplication region that is provided inside the semiconductor substrate to multiply the electric charge from the photoelectric conversion unit, and

first and second reflective portions that reflect light traveling toward outside the semiconductor substrate into the semiconductor substrate,

the first reflective portion is provided, on a first surface that receives light of the semiconductor substrate, to protrude from the pixel separation wall toward a pixel center, and

the second reflective portion is provided on a second surface of the semiconductor substrate facing the first surface.

### REFERENCE SIGNS LIST

10, 10a PIXEL
20 PHOTODIODE
22 CONSTANT CURRENT SOURCE
24 INVERTER
26 TRANSISTOR
100 SEMICONDUCTOR SUBSTRATE
100a BACK SURFACE
100b FRONT SURFACE
102 n-TYPE SUB-REGION
104 p-TYPE SEMICONDUCTOR REGION
106 n-TYPE SEMICONDUCTOR REGION
106a HIGH-CONCENTRATION n-TYPE SEMICONDUCTOR REGION
108 HOLE ACCUMULATION REGION
108a HIGH-CONCENTRATION p-TYPE SEMICONDUCTOR REGION
110 n-TYPE WELL REGION
120 PIXEL SEPARATION PORTION
122 REFLECTIVE PORTION
124 TRENCH
126 METAL FILM
130 CATHODE ELECTRODE
132 ANODE ELECTRODE
140 ON-CHIP LENS
150 MASK MATERIAL
160, 162 RESIST
501 PHOTODETECTION DEVICE
511 PIXEL DRIVE UNIT
512 PIXEL ARRAY UNIT
512c CENTRAL PORTION
512s END PORTION
513 MUX
514 TIME MEASUREMENT UNIT
515 INPUT/OUTPUT UNIT
522 PIXEL DRIVE LINE
611 DISTANCE MEASURING SYSTEM
612, 613 SUBJECT
621 ILLUMINATION DEVICE
622 IMAGING DEVICE
631 ILLUMINATION CONTROL UNIT
632 LIGHT SOURCE
641 IMAGING UNIT
642 CONTROL UNIT
643 DISPLAY UNIT
644 STORAGE UNIT
651 LENS
653 SIGNAL PROCESSING CIRCUIT
900 SMARTPHONE
901 CPU
902 ROM
903 RAM
904 STORAGE DEVICE
905 COMMUNICATION MODULE
906 COMMUNICATION NETWORK
907 SENSOR MODULE
909 IMAGING DEVICE
910 DISPLAY DEVICE
911 SPEAKER
912 MICROPHONE
913 INPUT DEVICE
914 BUS

What is claimed is:

1. A photodetection device, comprising:
a pixel array unit including a plurality of pixels that is arranged in a matrix on a semiconductor substrate to detect light, wherein
each of the pixels includes
a pixel separation wall that surrounds the pixels and separates the pixels from one another,
a photoelectric conversion unit that is provided inside the semiconductor substrate to generate an electric charge by light,
a multiplication region that is provided inside the semiconductor substrate to multiply the electric charge from the photoelectric conversion unit, and
first and second reflective portions that reflect light traveling toward outside the semiconductor substrate into the semiconductor substrate,
the first reflective portion is provided, on a first surface that receives light of the semiconductor substrate, to protrude from the pixel separation wall toward a pixel center, and
the second reflective portion is provided on a second surface of the semiconductor substrate facing the first surface.

2. The photodetection device according to claim 1, wherein in a case where the semiconductor substrate is seen from above the first surface, a width of the first reflective portion is larger than a width of the pixel separation wall.

3. The photodetection device according to claim 1, wherein in a case where the semiconductor substrate is seen from above the first surface, the first reflective portion is provided without overlapping with the multiplication region.

4. The photodetection device according to claim 1, wherein the first reflective portion includes at least one material selected from a group consisting of tungsten, aluminum, titanium, titanium nitride, and tungsten nitride.

5. The photodetection device according to claim 1, wherein
in a case where the semiconductor substrate is seen from above the first surface,
the pixel separation wall has a shape of a substantially rectangular frame surrounding each of the pixels.

6. The photodetection device according to claim 5, wherein
in a case where the semiconductor substrate is seen from above the first surface,
the first reflective portion is located at four corners of the substantially rectangular frame.

7. The photodetection device according to claim 5, wherein
in a case where the semiconductor substrate is seen from above the first surface,
the first reflective portion is located at four sides of the substantially rectangular frame.

8. The photodetection device according to claim 1, wherein each of the pixels includes, on the first surface, a lens unit that has a function to refract light from outside so as not to be reflected by the first reflective portion.

9. The photodetection device according to claim 8, wherein
according to a distance from a center of the pixel array unit of each of the pixels,
a height of the lens unit with respect to the first surface is changed.

10. The photodetection device according to claim 1, wherein
the multiplication region includes
a first semiconductor region that is provided on the second surface side of the photoelectric conversion unit and contains a first conductivity type impurity, and
a second semiconductor region that is provided on the second surface side of the first semiconductor region and contains a second conductivity type impurity, the second conductivity type being a conductivity type opposite to the first conductivity type.

11. The photodetection device according to claim 10, wherein
each of the pixels includes
a third semiconductor region that is provided on the second surface side of the second semiconductor region and contains the second conductivity type impurity, and
concentration of the impurity of the third semiconductor region is lower than that of the second semiconductor region.

12. The photodetection device according to claim 11, wherein
the concentration of the impurity of the third semiconductor region is higher than that of the semiconductor substrate.

13. The photodetection device according to claim 11, wherein the third semiconductor region is thicker than the multiplication region.

14. The photodetection device according to claim 1, wherein the second reflective portion includes a cathode portion that is electrically connected to the multiplication region.

15. The photodetection device according to claim 14, wherein
each of the pixels includes a hole accumulation region that covers an inner surface of the pixel separation wall.

16. The photodetection device according to claim 15, wherein the second reflective portion includes an anode portion that is provided on the second surface side of the hole accumulation region.

17. The photodetection device according to claim 7, wherein
as the pixel array unit extends away from a center thereof toward an end portion thereof along a first direction,
a distance protruding from the pixel separation wall toward the pixel center along a second direction perpendicular to the first direction becomes longer.

18. The photodetection device according to claim 17, wherein
as the pixel array unit extends away from the center thereof toward the end portion thereof along the second direction,
the distance protruding from the pixel separation wall toward the pixel center along the first direction becomes longer.

19. An electronic device mounting a photodetection device, the photodetection device including
a pixel array unit including a plurality of pixels that is arranged in a matrix on a semiconductor substrate to detect light, wherein
each of the pixels includes
a pixel separation wall that surrounds the pixels and separates the pixels from one another,
a photoelectric conversion unit that is provided inside the semiconductor substrate to generate an electric charge by light,
a multiplication region that is provided inside the semiconductor substrate to multiply the electric charge from the photoelectric conversion unit, and
first and second reflective portions that reflect light traveling toward outside the semiconductor substrate into the semiconductor substrate,
the first reflective portion is provided, on a first surface that receives light of the semiconductor substrate, to protrude from the pixel separation wall toward a pixel center, and
the second reflective portion is provided on a second surface of the semiconductor substrate facing the first surface.

20. A distance measuring system, comprising:
an illumination device that emits irradiation light; and
a photodetection device that receives reflected light obtained by reflecting the irradiation light being reflected by a subject, wherein
the photodetection device includes
a pixel array unit including a plurality of pixels that is arranged in a matrix on a semiconductor substrate to detect light,
each of the pixels includes
a pixel separation wall that surrounds the pixels and separates the pixels from one another,
a photoelectric conversion unit that is provided inside the semiconductor substrate to generate an electric charge by light,
a multiplication region that is provided inside the semiconductor substrate to multiply the electric charge from the photoelectric conversion unit, and
first and second reflective portions that reflect light traveling toward outside the semiconductor substrate into the semiconductor substrate,
the first reflective portion is provided, on a first surface that receives light of the semiconductor substrate, to protrude from the pixel separation wall toward a pixel center, and
the second reflective portion is provided on a second surface of the semiconductor substrate facing the first surface.
